(19) United States
(12) Patent Application Publication
(10) Pub. No.: US 2016/0359110 A1
(43) Pub. Date: Dec. 8, 2016

(54) SWITCHING ELEMENT, AND METHOD FOR PRODUCING SWITCHING ELEMENT

(71) Applicant: NEC CORPORATION, Tokyo (JP)

(72) Inventors: Naoki BANNO, Tokyo (JP); Munehiro TADA, Tokyo (JP); Koichiro OKAMOTO, Tokyo (JP)

(21) Appl. No.: 15/120,993

(22) PCT Filed: Feb. 18, 2015
(86) PCT No.: PCT/JP2015/000758

§ 371 Date: Aug. 23, 2016

(30) Foreign Application Priority Data
Mar. 7, 2014 (JP) 2014-045013

(51) Int. Cl. H01L 45/00; H01L 23/522; H01L 23/532

(52) U.S. Cl. CPC H01L 45/1266; H01L 45/08; H01L 45/145; H01L 45/1233; H01L 23/53228; H01L 23/5226

(57) ABSTRACT

Provided is a nonvolatile switching element which has high retention ability even if programmed at a low current, while being suppressed in dielectric breakdown of a variable resistance layer during a reset operation. This switching element is provided with: a first electrode; a second electrode; and a variable resistance layer that is arranged between the first electrode and the second electrode and has ion conductivity. The first electrode contains a metal which generates metal ions that can be conducted in the variable resistance layer. The second electrode is provided with: a first electrode layer that is formed in contact with the variable resistance layer; and a second electrode layer that is formed in contact with the first electrode layer. The first electrode layer is formed of a ruthenium alloy that contains ruthenium and a first metal having a larger standard Gibbs energy of formation of oxide than ruthenium in the negative direction. The second electrode layer is formed of a nitride that contains the first metal. The content of the first metal in the first electrode layer is lower than the content of the first metal in the second electrode layer.

### TECHNICAL FIELD

The present invention relates to a switching element and a method for producing a switching element, especially relates to a switching element that forms a metal bridge utilizing an electrochemical reaction in an ion conductive layer conducting metal ions, such that the resistance can change from an off-state to an on-state, and a method for producing the same. Such formation of a metal bridge utilizing an electrochemical reaction means formation of a metal bridge in a variable resistance layer (ion conductive layer) by means of generation of a metal ion by oxidation of a metal, introduction of the generated metal ion, and precipitation of the metal by reduction of the metal ion.

### BACKGROUND ART

For promotion of mounting on to an electronic device, etc. by diversifying programmable logic functions, it is required to decrease the size of a switch connecting logic cells together, and to decrease the on-resistance. As a device able to satisfy such requirements, a nonvolatile switching element has been developed, which forms a metal bridge in a variable resistance layer utilizing an electrochemical reaction, and performs therewith switching from an off-state to an on-state. In other words, switching from an off-state to an on-state is performed by forming a metal bridge in a variable resistance layer by precipitating a metal in the variable resistance layer (ion conductive layer) for conducting a metal ion utilizing an electrochemical reaction. It has been known that such a nonvolatile switching element has a size smaller than a conventional semiconductor switch, and has a low on-resistance.

As a nonvolatile switching element utilizing an electrochemical reaction, there have been a “two-terminal switch” disclosed in PTL1 (International Publication No. 00/48196) and a “three-terminal switch” disclosed in PTL2 (International Publication No. 2012/043502). FIG. 1A is a cross-sectional view showing the constitution of a switching element configured as a two-terminal switch disclosed in PTL1. PTL1 discloses that a switching element has a structure in which an ion conductive layer 203 is sandwiched between a lower electrode 201 that supplies a metal ion in a changing process of the switching element from an off-state to an on-state, and an upper electrode 202 that does not supply a metal ion.

In a changing process for the switching element from an off-state to an on-state, the upper electrode 202 is grounded, and a positive voltage is applied to the lower electrode 201. At the lower electrode 201 a metal is ionized and a generated metal ion is introduced into the ion conductive layer 203. At the upper electrode 202, the metal ion is reduced to be precipitated. By the precipitated metal, a metal bridge is formed in the ion conductive layer 203 extending from the upper electrode 202 to the lower electrode 201, and as the result the switching element is switched from an off-state to an on-state. Conversely, in a changing process for the switching element from an on-state to an off-state, the upper electrode 202 is grounded, and a negative voltage is applied to the lower electrode 201. By this a precipitated metal is re-ionized, and at the lower electrode 201 re-precipitation of a metal proceeds by reduction of a metal ion. As the result, the metal bridge disappears and the switching element is switched from an on-state to an off-state. Since a two-terminal switch has a simple structure, the production process can be simple, and therefore fabrication of a two-terminal switch with a device size in a nanometer order is even possible.

Meanwhile, FIG. 1B is a schematic diagram showing the constitution of a switching element configured as the three-terminal switch disclosed in PTL2. PTL2 discloses that a switching element is provided with a first switch 301 and a second switch 302 (refer to FIG. 3 in PTL2). The first switch 301 is provided with a first electrode 301a configured as an active electrode, a second electrode 301b configured as an inactive electrode, and a variable resistance layer sandwiched by the two.

Similarly, the second switch 302 is provided with a first electrode 302a configured as an active electrode, a second electrode 302b configured as an inactive electrode, and a variable resistance layer sandwiched by the two. In the first switch 301, the first electrode 301a is connected with a first node 303, and in the second switch 302, the first electrode 302a is connected with a second node 304. In the first switch 301 and the second switch 302, the second electrodes 301b and 302b are connected with a common node 305. By regulating a voltage VL1 applied to the first node 303 and a voltage VL2 applied to the second node 304, the switching element is switched between an on-state and an off-state. Since the switching element disclosed in PTL2 has a structure in which inactive electrodes of two of the two-terminal switches are integrated, high reliability can be secured.

PTL3 (International Publication No. 2011/058947) discloses a preferable material for a variable resistance layer (ion conductive layer) for a nonvolatile switching element utilizing an electrochemical reaction. PTL3 discloses use of a porous polymer containing silicon, oxygen, and carbon as main components for a variable resistance layer. Since a porous polymer ion conductive layer can maintain the dielectric breakdown voltage high, even when a metal bridge is formed, it is superior in operational reliability.

For installing (applying) a nonvolatile switching element as a switch for switching programmable logic wiring, it is necessary to reduce the device size and simplify a production process corresponding to wiring densification. For a most advanced semiconductor device, copper is mainly applied as a wiring material utilized for forming multilayer wiring. There has been a demand for a technique for forming efficiently a nonvolatile switching element in a copper wiring having a multilayer structure.

A technique for integrating a switching element utilizing an electrochemical reaction in a semiconductor device is, for example, disclosed in NPL1. NPL1 describes a configuration in which copper wiring on a semiconductor substrate serves also as a lower electrode of a switching element in producing a lower electrode of a switching element from copper. By adopting such a structure, a step for forming newly a lower electrode on top of copper wiring can be omitted, and a mask for a patterning step for producing a lower electrode becomes unnecessary. For example, for producing a variable resistance element having a configuration of a two-terminal switch, it is only necessary to add two sheets of photomasks (PR: photoresist mask) to be used at a step for forming an ion conductive layer, and a step for forming an upper electrode.

When a lower electrode of a switching element is produced with copper, an upper electrode, which does not supply a metal ion during a process for switching a switching element from an off-state to an on-state, is formed with platinum or gold, which is hardly oxidized, or ruthenium, which is electrically conductive even when it is oxidized. NPL1 discloses a case, in which ruthenium suitable for processing is used for producing an upper electrode.

In a case in which copper wiring on a semiconductor substrate is used also as a lower electrode of a switching element, when a porous polymer ion conductive layer is formed with a porous polymer containing as main components silicon, oxygen, and carbon is formed directly on copper wiring, the copper wiring surface suffers oxidation. PTL3 discloses a technique by which a metal thin film functioning as an oxidizing sacrificial layer is provided on the copper wiring surface for purpose of preventing the copper wiring surface from oxidation, and then a porous polymer ion conductive layer is formed. The metal thin film is oxidized by oxygen during a step for depositing a porous polymer ion conductive layer, and converted to a thin film of a metal oxide exhibiting ion conductivity.

FIG. 1C is a cross-sectional view showing specifically the constitution of a switching element disclosed in PTL3. PTL3 is provided with a first electrode 401, a second electrode 402, an ion conductive layer 403, and a titanium oxide film 404 (refer to FIG. 4 in PTL3). The ion conductive layer 403 and the titanium oxide film 404 are disposed between the first electrode 401 and the second electrode 402.

The first electrode 401 is formed with a metal containing copper as a main component, and the titanium oxide film 404 is disposed between the ion conductive layer 403 and the first electrode 401. The ion conductive layer 403 is formed with a porous polymer containing silicon, oxygen, and carbon as main components. Meanwhile, the titanium oxide film 404 is formed by oxidation of a titanium film (a metal thin film functioning as an oxidized sacrificial layer) during formation of the ion conductive layer 403. The titanium oxide film 404 constitutes, together with the ion conductive layer 403 to be deposited on the upper surface thereof, a variable resistance layer exhibiting ion conductivity.

PTL4 relates to a semiconductor device, and proposes a semiconductor device having a three-terminal variable resistance element inside a multilayer copper wiring layer on a semiconductor substrate. PTL5 relates to a variable resistance element provided with a variable resistance layer sandwiched by a lower electrode and an upper electrode, and lists material names for a lower electrode and an upper electrode of the variable resistance element disclosed by PTL5. PTL5 describes that an upper electrode according to PTL5 may be formed with Au, Pt, Ru, Ir, Ti, Al, Cu, Ta, etc., or an alloy, an oxide, a nitride, a fluoride, a carbide, a boride, etc. thereof. It is described further that an upper electrode according to PTL5 is preferably formed with a material that is hardly oxidized, or a material that can maintain electrical conductivity even after oxidation, and preferably formed with a nitride, such as Ti—N (titanium nitride), FeN (iron nitride), and Ti—Al—N. PTL6 relates to a variable resistance element, and proposes use of an alloy of ruthenium and a metal having a standard Gibbs energy of formation with respect to oxidation negatively larger than ruthenium, for an electrode of the variable resistance element.

### CITATION LIST

### Patent Literature

[PTL1] International Publication No. 00/48196
[PTL2] International Publication No. 2012/043502
[PTL3] International Publication No. 2011/058947
[PTL4] International Publication No. 2011/158821
[PTL5] Japanese Patent Application Laid-Open No. 2007-288008
[PTL6] International Publication No. 2013/190988

### Non Patent Literature

[NPL1] IEEE Transactions on Electron Devices, vol. 57, pp. 1987-1995, 2010

### SUMMARY OF INVENTION

### Technical Problem

A nonvolatile switching element utilizing an electro-chemical reaction is applicable to a selector switch for a programmable logic wiring. In using a nonvolatile switching element as a selector switch for a programmable logic wiring, there are two issues to be achieved.

The first issue is improvement of the yield rate of a switching element, which is capable of surely rewriting to an on-state, or an off-state. In the event of a reset action conducting a transit to an off-state using large-scale device arrays, some elements may remain unreset. Such elements once exhibit a resetting behavior so that the resistance value of the element increases, however the same transits again to a low resistance state at a voltage lower in absolute value than a desired reset voltage. In such elements, after a metal bridge in a variable resistance layer (ion conductive layer) is withdrawn by a reset action, the variable resistance layer undergoes dielectric breakdown. To eliminate such a problem, the constitution of a nonvolatile switching element is required to be optimized.

The second issue is improvement of the holding ability of an on-state or an off-state for approximately 10 years in a condition without application of voltage or current to be used for rewriting after completion of rewriting to an on-state or an off-state during initial programming. The amperage to be used for rewriting is proportional to the total amount of a metal constituting a metal bridge to be formed in a variable resistance layer (ion conductive layer). For forming a thick metal bridge, the total amount of a metal constituting the metal bridge needs to be large, and therefore the amperage to be used for rewriting needs to be large. Conversely, when the amperage used for rewriting is small, the total amount of a metal for constituting a metal bridge becomes small and a metal bridge to be formed becomes thin. In a case in which a “thin metal bridge” is used, over a long period of time, thinning occurs locally in the “thin metal bridge” due to electro-migration and metal ionization caused by current flowing through the “thin metal bridge”, and the resistance value of a nonvolatile switching element may increase suddenly. Since electro-migration and metal ionization is accelerated by temperature increase, wire breaking may eventually take place locally in the “thin metal bridge”. In other words, with respect to a nonvolatile switching element, there exists a trade-off between reduction of the amperage to be used for rewriting (low power) and the holding ability of a low resistance value of the on-state for a long period of time (high reliability). For achieving high reliability for a long period beyond 10 years, and at the same time for promoting reduction of the amperage used for rewriting (low power), the constitution of a nonvolatile switching element is required to be optimized.

The present invention is to achieve the above issues. An object of the present invention is to provide a nonvolatile switching element that suppresses dielectric breakdown in a variable resistance layer during a reset action, and at the same time has high holding ability even in a case of programming with a low current.

### Solution to Problem

In an aspect of the present invention, a switching element includes a first electrode, a second electrode, and a variable resistance layer with ion-conductivity disposed between the first electrode and the second electrode. The first electrode includes a metal that generates a metal ion conductive in the variable resistance layer. The second electrode is provided with a first electrode layer formed in contact with the variable resistance layer, and a second electrode layer formed in contact with the first electrode layer. The first electrode layer is made of a ruthenium alloy containing ruthenium and a first metal with a standard Gibbs energy of formation with respect to an oxidation process larger in the negative direction than ruthenium, and the second electrode is formed with a nitride containing the first metal. A content of the first metal in the first electrode layer is lower than the content of the first metal in the second electrode layer.

In the other aspect of the present invention, a semiconductor device is provided with a semiconductor substrate, and a multilayered wiring layer including a copper-made wiring and a copper-made plug, formed over the semiconductor substrate. A switching element is formed in the multilayered wiring layer. The switching element is provided with a copper-made lower electrode copper wiring to be used as a lower electrode of the switching element, an upper electrode electrically connected with the plug, and a variable resistance layer with ion-conductivity formed between the lower electrode copper wiring and the upper electrode. The upper electrode is provided with a first upper electrode layer formed in contact with the variable resistance layer, and a second upper electrode layer formed in contact with the first upper electrode layer. The first upper electrode layer is made of a ruthenium alloy containing ruthenium and a first metal with a standard Gibbs energy of formation with respect to an oxidation process larger in the negative direction than ruthenium. The second upper electrode is formed with a nitride containing the first metal. A content of the first metal in the first upper electrode layer is lower than the content of the first metal in the second upper electrode layer.

### Advantageous Effect of Invention

According to the present invention, a nonvolatile switching element that suppresses dielectric breakdown in a variable resistance layer during a reset action, and at the same time has high holding ability even in a case of programming with a low current is provided.

### BRIEF DESCRIPTION OF DRAWINGS

FIG. 1A is a cross-sectional view schematically showing an example of the structure of a switching element adopting a configuration of a two-terminal switch.

FIG. 1B is a cross-sectional view schematically showing an example of the structure of a switching element adopting a configuration of a three-terminal switch.

FIG. 1C is a cross-sectional view schematically showing an example of the structure of a switching element provided with a titanium oxide film and a porous polymer ion conductive layer formed on the upper surface thereof.

FIG. 2 is a cross-sectional view schematically showing an example of the structure of a switching element according to the first exemplary embodiment.

FIG. 3 is a cross-sectional view schematically showing a mechanism of formation of a metal bridge in an ion conductive layer during a switching process from an off-state to an on-state in a switching element according to the first exemplary embodiment.

FIG. 4 is cross-sectional views schematically showing a method for producing a switching element according to the first exemplary embodiment.

FIG. 5 is a cross-sectional view schematically showing an exemplary configuration of a semiconductor device in which a switching element according to the first exemplary embodiment is formed inside a multilayer wiring layer.

FIG. 6A is a graph showing a distribution of the retention characteristics of the resistance value in an on-state of a switching element, in which a first upper electrode layer is formed with ruthenium.

FIG. 6B is a graph showing a distribution of the retention of the resistance value in an on-state of a switching element, in which a first upper electrode layer is formed with a ruthenium alloy containing 25 atm % of titanium.

FIG. 6C is a graph showing a distribution of the current value required for switching a switching element, in which a first upper electrode layer is formed with ruthenium, into an off-state.

FIG. 6D is a graph showing a distribution of the current value required for switching a switching element, in which a first upper electrode layer is formed with a ruthenium alloy containing 25 atm % of titanium, into an off-state.

FIG. 7A is a figure showing a cross-sectional TEM (Transmission Electron Microscope) image of a switching element according to the first exemplary embodiment.

FIG. 7B is a graph showing the reset yield rate of a switching element according to the first exemplary embodiment.

FIG. 8A is cross-sectional views schematically showing steps 1 to 4 of a method for producing a switching element according to the first exemplary embodiment.

FIG. 8B is cross-sectional views schematically showing steps 5 to 8 of a method for producing a switching element according to the first exemplary embodiment.

FIG. 8C is cross-sectional views schematically showing steps 9 and 10 of a method for producing a switching element according to the first exemplary embodiment.

FIG. 8D is cross-sectional views schematically showing steps 11 and 12 of a method for producing a switching element according to the first exemplary embodiment.

FIG. 9 is a cross-sectional view schematically showing an exemplary configuration of a semiconductor device according to the second exemplary embodiment.

FIG. 10A is cross-sectional views schematically showing steps 1 to 3 of a method for producing a switching element according to the second exemplary embodiment.

FIG. 10B is cross-sectional views schematically showing steps 4 to 6 of a method for producing a switching element according to the second exemplary embodiment.

FIG. 10C is cross-sectional views schematically showing steps 7 to 9 of a method for producing a switching element according to the second exemplary embodiment.

FIG. 10D is cross-sectional views schematically showing steps 10 and 11 of a method for producing a switching element according to the second exemplary embodiment.

FIG. 10E is a cross-sectional view schematically showing Step 12 of a method for producing a switching element according to the second exemplary embodiment.

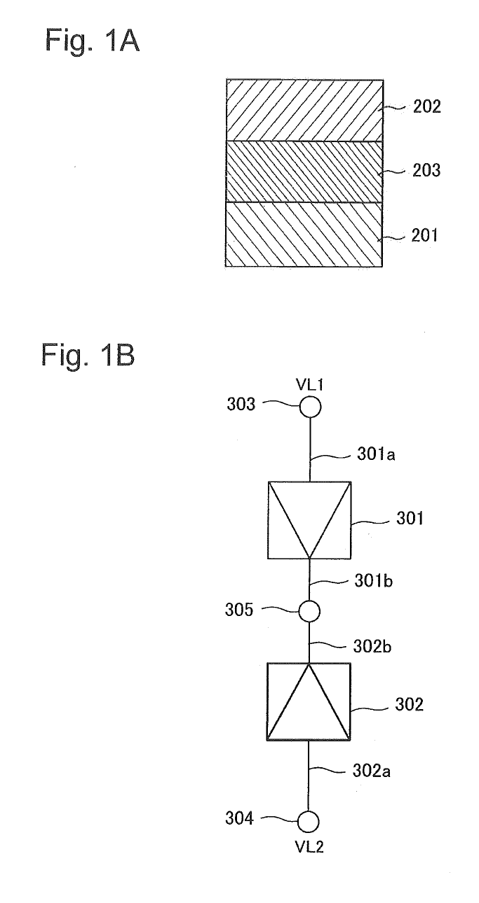

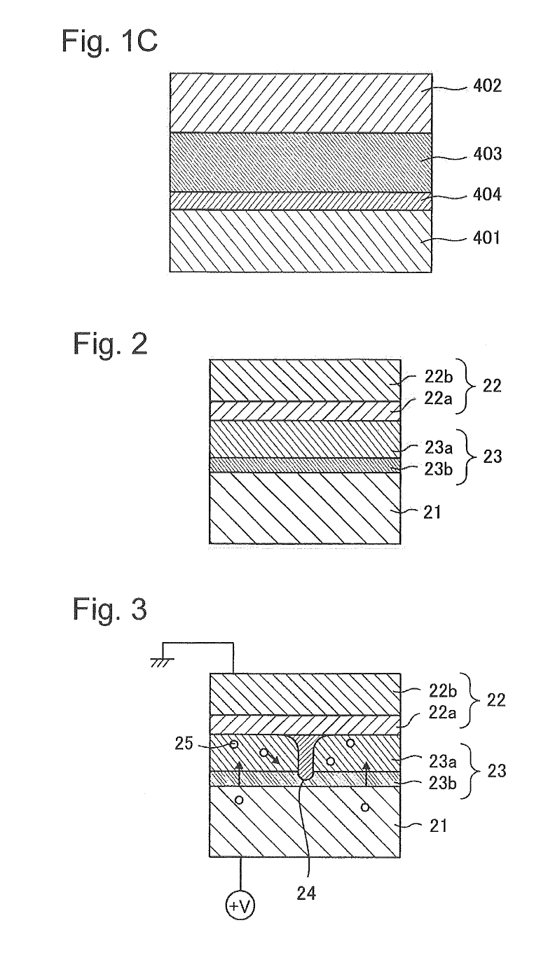

### DESCRIPTION OF EMBODIMENTS

According to an exemplary embodiment of the present invention, a switching element (variable resistance element) includes a first electrode and a second electrode, as well as a variable resistance layer with ion-conductivity provided between the first electrode and the second electrode. The first electrode contains a metal which can be conducted to a variable resistance layer. The second electrode is provided with a first electrode layer to be formed in contact with the variable resistance layer, and a second electrode layer to be formed in contact with the first electrode layer. The first electrode layer is formed with an alloy containing ruthenium and a first metal. The second electrode layer is formed with a nitride containing the first metal. The content of the first metal in the first electrode layer is lower than the content of the first metal in the second electrode layer.

When the second electrode layer is formed with a nitride of a metal, diffusion of a first metal composing the second electrode layer through the first electrode layer into the variable resistance layer due to a damage received in a heating step or a plasma step in a process for forming a switching element can be prevented. When a metal composing the second electrode layer diffuses into a variable resistance layer, a defect is generated inside the variable resistance layer to decrease a dielectric breakdown voltage. By forming the second electrode layer with a nitride, a dielectric breakdown of a variable resistance layer associated with a reset action can be prevented to improve the reset yield. By this means, a trouble during resetting can be prevented and the repeat frequency of switching can be secured.

Meanwhile, by adding a first metal to ruthenium composing the first electrode layer, the adherence between a metal bridge and the first electrode layer is improved, and therefore the stability of an element is improved even when programming is carried out with a low current and the holding ability is improved. Further, since the first electrode layer contains ruthenium, reset can be carried out stably. Furthermore, since by alloying the first electrode layer the specific resistance increases, heat generation is promoted by a rewriting current, such that the Joules heat generated at a metal bridge dissipates hardly due to a heat confining effect. This gives also an effect to reduce a rewriting current necessary for rewriting.

In this case, the content of the first metal in the first electrode layer is so regulated that the same is lower than the content of the first metal in the second electrode layer. By the regulation of the content, the composition of a ruthenium alloy composing the first electrode layer can be prevented from changing due to diffusion of the first metal contained in the first electrode layer into a nitride composing the second electrode layer.

A switching element according to the present exemplary embodiment can effectuate according to the above mechanism both of power reduction and holding ability improvement. If simply holding ability improvement is aimed at, it becomes necessary higher electric power for programming, however by improving heat efficiency using an alloy as the first electrode layer, programming can be carried out effectively even with a small current. More specific exemplary embodiment of a switching element according to the present invention will be described below in detail.

### First Exemplary Embodiment

FIG. 2 is a cross-sectional view schematically showing an example of the configuration of a switching element according to the first exemplary embodiment. A switching element according to the first exemplary embodiment is configured as a two-terminal switch, and provided with a lower electrode 21 (first electrode), and an upper electrode 22 (second electrode) as well as a variable resistance layer 23 provided between the two. The variable resistance layer 23 has ion conductivity and is a medium conducting a metal ion.

A lower electrode 21 functions as an active electrode which supplies a metal ion to a variable resistance layer 23, and formed, for example, with copper. As described below, a metal bridge is formed in a variable resistance layer 23, when a metal ion (copper ion) supplied from the lower electrode 21 to the variable resistance layer 23 is returned to a metal. A copper wiring formed by, for example, a sputtering method, a chemical vapor deposition method (CVD method), or an electrical plating method may be used as the lower electrode 21.

An upper electrode 22 functions as an inactive electrode. According to the present exemplary embodiment, an upper electrode 22 is configured as a laminate of a first upper electrode layer 22a and a second upper electrode layer 22. The first upper electrode layer 22a is formed in contact with a variable resistance layer 23, and the second upper electrode layer 22b is formed in contact with the first upper electrode layer 22a.

According to the present exemplary embodiment, as a material for a first upper electrode layer 22a, a ruthenium alloy (an alloy containing ruthenium as a main component), to which a first metal is added, is used. As the result of an investigation by the inventors, it is desirable to select a metal, whose standard Gibbs energy of formation with respect to an oxidation process (a process for forming a metal ion from a metal) is larger than ruthenium in the negative direction, as the first metal to be added to the ruthenium alloy in the first upper electrode layer 22a.

The “standard Gibbs energy of formation with respect to an oxidation process is larger than ruthenium in the negative direction” of a metal means in a precise sense the following status. That is, the standard Gibbs energy of formation with respect to an oxidation process of the metal is negative, and the absolute value of the standard Gibbs energy of formation with respect to an oxidation process of the metal is larger than the absolute value of the standard Gibbs energy of formation with respect to an oxidation process of ruthenium.

A metal, whose standard Gibbs energy of formation with respect to an oxidation process is larger than ruthenium in the negative direction, such as titanium, tantalum, zirconium, hafnium, and aluminum, tends to undergo a chemical reaction (for example, oxidation reaction) spontaneously compared to ruthenium. When a ruthenium alloy containing a first metal having such tendency is used as a material for forming a first upper electrode layer 22a, adherence to a metal bridge to be formed in a variable resistance layer 23 is enhanced. The content of the first metal in the ruthenium alloy is preferably in a range from 10 atm % or more to 40 atm % or less.

A first metal to be added to the ruthenium alloy is preferably a metal selected from the group consisting of titanium, tantalum, zirconium, hafnium, and aluminum. The first metal may be two or more metals selected from the group consisting of titanium, tantalum, zirconium, hafnium, and aluminum.

It should be noted that, when a first upper electrode layer 22a is composed solely of a first metal, transit to an off-state becomes impossible. In other words, transit from an on-state to an off-state is promoted by an oxidation reaction (dissolving reaction) of copper to form a metal bridge. When the standard Gibbs energy of formation with respect to an oxidation process of a first metal composing a first upper electrode layer 22a is larger in the negative direction than copper composing a metal bridge, an oxidation reaction of the first metal composing the first upper electrode layer 22a proceeds in preference to an oxidation reaction of copper composing a metal bridge. In this regard, an oxidation process of a first metal means a process that forms a metal ion from a metal of a first metal composing a first upper electrode layer 22a. Since the oxidation reaction of a first metal proceeds preferentially, dissolution of a metal bridge does not proceed, so that transit from an on-state to an off-state becomes impossible.

Consequently, a first upper electrode layer 22a is desirably composed of an alloy of a first metal and ruthenium, whose standard Gibbs energy of formation with respect to a process forming a metal ion from a metal (oxidation process) is smaller in the negative direction than copper. Specifically, it has been empirically known that, when the content of a first metal in an alloy is 40 atm % or more, dielectric breakdown of an ion conductive layer occurs by application of a negative voltage to a lower electrode 21 in a transit process from an on-state to an off-state, so that transit to an off-state is inhibited.

Meanwhile, it has been known that an on-state is more stabilized, when the amount of a first metal is larger, and that even addition of 5 atm % can improve the stability.

In order to suppress deterioration of switching characteristics in a switching process from an on-state to an off-state, and at the same time to improve the stability of an on-state, it is preferable to select the composition of a ruthenium alloy, so as to limit the content of a first metal within a predetermined range. The predetermined range of the content of a first metal is a range of the content of a first metal between 10 atm % or more and 40 atm % or less. Thus, compared to a case where a first upper electrode layer 22a is formed solely with ruthenium, deterioration of the switching characteristics can be suppressed, and at the same time the stability of an on-state can be improved. In this case the content of ruthenium in the ruthenium alloy is not less than 60 atm % and 90 atm %.

A material for a first upper electrode layer 22a is desirably selected such that a metal ion is not supplied to a variable resistance layer 23, when an upper electrode 22 is grounded and a positive voltage is applied to a lower electrode 21 in a process switching from an off-state to an on-state.

For forming a first upper electrode layer 22a, use of a sputtering method is desirable. For depositing a ruthenium alloy film by a sputtering method, there are a method by which a target of an alloy of ruthenium and a first metal is used, and a co-sputtering method by which sputtering is conducted simultaneously with a target of ruthenium and a target of a first metal in the same chamber. Moreover, for depositing a ruthenium alloy film by a sputtering method, there is an intermixing method, by which a thin film of a first metal is formed in advance, and ruthenium is deposited thereon using a sputtering method, during which an alloy is formed by the energy of colliding atoms. By using a co-sputtering method or an intermixing method, the composition of an alloy can be modified. When an intermixing method is applied, it is preferable to conduct a heat treatment at 400° C. or less for homogenizing the mixture condition after completing deposition of a ruthenium film.

When copper, which is a component of a metal bridge, gets mixed in a first upper electrode layer 22a, an effect of addition of a metal whose standard Gibbs energy of formation in the negative direction is large, is weakened, and therefore a first metal to be added to a ruthenium alloy should preferably be a material having a barrier property against copper, and a copper ion. Examples thereof include tantalum, and titanium. Especially, when titanium is used as a first metal, it is superior in transit to off and stability of an on-state, and therefore it is especially preferable that a first upper electrode layer 22a is formed with a ruthenium alloy containing titanium, and the titanium content is regulated to a range from 20 atm % or more to 30 atm % or less.

A second upper electrode layer 22b has a function to protect a first upper electrode layer 22a against an etching damage. Specifically, in processing a first upper electrode layer 22a into a specified device size, a second upper electrode layer 22b should be configured such that the first upper electrode layer 22a involved in a switching action should not be exposed directly. Specifically, when a contact hole for forming a via contact to establish an electrical connection from the outside to a first upper electrode layer 22a is formed, a second upper electrode layer 22b should be configured such that the first upper electrode layer 22a involved in a switching action should not be exposed directly. A second upper electrode layer 22b has also a function of an etching-stop film in etching a contact hole during formation of a contact hole. Therefore, a second upper electrode layer 22b is preferably formed with a material, whose etching speed with respect to a gas plasma based on fluorocarbon to be used for etching an insulation film such as silicon oxide, where a contact hole is to be formed.

According to the present exemplary embodiment, a second upper electrode layer 22b is composed of a nitride of a first metal contained in a ruthenium alloy composing a first upper electrode layer 22a. As described above, a first metal is preferably selected from the group consisting of titanium, tantalum, zirconium, hafnium, and aluminum. Thus, a nitride of a first metal composing a second upper electrode layer 22b functions as an etching-stop film and at the same time has electrical conductivity.

There appears the following possibility, when a metal other than a nitride is used for a second upper electrode layer 22b. In other words, a part of metal may diffuse into a first upper electrode layer 22a due to heating or plasma damage in a process to generate defects in the first upper electrode layer 22a, so that the dielectric breakdown voltage of an ion conductive layer may decrease originating from such defects.

By using a stable metal nitride, which is a compound having electrical conductivity, for a second upper electrode layer 22b, diffusion of the metal into a first upper electrode layer 22a can be prevented. Especially, if a metal of a nitride composing a second upper electrode layer 22b and a first metal contained in a ruthenium alloy composing a first upper electrode layer 22a are the same, it is appropriate because generation of a defect due to diffusion of the first metal contained in a ruthenium alloy can be prevented more efficiently.

When, for example, a first upper electrode layer 22a is formed with a ruthenium alloy containing titanium, a second upper electrode layer 22b is preferably formed with titanium nitride. Alternatively, when a first upper electrode layer 22a is formed with a ruthenium alloy containing tantalum, a second upper electrode layer 22b is preferably formed with tantalum nitride. By using the same metal component to be contained in a first upper electrode layer 22a and a second upper electrode layer 22b, even when a metal in the second upper electrode layer 22b diffuses into the first upper electrode layer 22a, a defect is hardly generated.

In this case, the content of a first metal in a ruthenium alloy composing a first upper electrode layer 22a is selected lower than the content of the first metal in a nitride composing a second upper electrode layer 22b. By this means, the composition of a ruthenium alloy composing a first upper electrode layer 22a is prevented from changing due to diffusion of a first metal contained in a first upper electrode layer 22a to a second upper electrode layer 22b. Specifically, when a second upper electrode layer 22b is formed with titanium nitride, the content of titanium in the second upper electrode layer 22b is preferably from 40 atm % to 80 atm %. When a composition outside the range is adopted, intermixing between a first upper electrode layer 22a and a second upper electrode layer 22b is likely to occur easily due to a thermal load, etc. during processing at a later step, so that switching characteristics are deteriorated.

A sputtering method is desirably used for forming a second upper electrode layer 22b. When a metal nitride is formed into a film using a sputtering method, it is preferable to use a reactive sputtering method, by which a metal target is evaporated using plasma of a mixture gas of nitrogen and argon. A metal evaporated from a metal target reacts with nitrogen to form a metal nitride and is deposited on a substrate.

A variable resistance layer 23 has ion conductivity, and functions as a medium for transmitting a metal ion supplied from a lower electrode 21. According to the present exemplary embodiment, a variable resistance layer 23 is provided with a first ion conductive layer 23a and a second ion conductive layer 23b.

According to the present exemplary embodiment, a first ion conductive layer 23a is constituted at least with a film containing silicon, oxygen, and carbon as main components, more specifically with a SiOCH polymer (for example, a polymer of an organic silica compound such as cyclic siloxane) containing silicon, oxygen, carbon, and hydrogen. A SiOCH polymer film to be used as a first ion conductive layer 23a may be deposited by a plasma-enhanced CVD method. In this regard, a plasma-enhanced CVD method is a technique, by which for example, a gaseous source material, or a vaporized liquid source material is supplied continuously in a reaction chamber under reduced pressure, and the molecule is activated to an excited state by plasma energy, so that a continuous film is formed on a substrate by a gas phase reaction, a substrate surface reaction, or the like. According to an exemplary embodiment, a SiOCH polymer film to be used as a first ion conductive layer 23a is formed as follows. A source material for a cyclic organic siloxane, and helium as a carrier gas are supplied in a reaction chamber, and when the supply of the both is stabilized such that the reaction chamber pressure becomes constant, application of RF (Radio Frequency) power is initiated. The supply rate of the source material is from 10 to 200 sccm, and with respect to helium, 500 sccm of helium is supplied through a source material vaporizer, and 500 sccm of helium is supplied directly into a reaction chamber through a separate line. The relative dielectric constant of a first ion conductive layer 23a is preferably from 2.1 or more to 3.1 or less.

A second ion conductive layer 23b is inserted between a lower electrode 21 and a first ion conductive layer 23a and formed with a metal oxide. A second ion conductive layer 23b is formed by oxidizing a thin film of a metal composing the metal oxide (hereinafter referred to as “second metal”). More precisely, a thin film of the second metal is firstly formed on a lower electrode 21. Then, a SiOCH polymer film to constitute a first ion conductive layer 23a is deposited on the thin film of the second metal by a plasma-enhanced CVD method. In depositing a SiOCH polymer film, the thin film of the second metal is oxidized by oxygen present in a reaction chamber (film deposition chamber), thereby forming a thin film of a metal oxide to be used as a second ion conductive layer 23b.

A second metal composing the metal oxide is preferably a metal, whose standard Gibbs energy of formation in the negative direction is large, and may be selected from the group consisting of titanium, aluminum, zirconium, hafnium, and tantalum. The metals may be layered one on another and used as a thin film of a second metal. The optimum thickness of a thin film of a second metal is from 0.5 nm to 1 nm. When the thickness is less than the optimum value, oxidation extends beyond the thin film of a second metal to reach a copper wiring surface, during a SiOCH polymer film is deposited by a plasma-enhanced CVD method. As the result, oxidation of a copper wiring surface occurs to a limited extent. Meanwhile, when the standard Gibbs energy of formation of a second metal composing a metal oxide for a second ion conductive layer 23b is too large, or the thickness is larger than the optimum value, oxidation of a thin film of the metal may not be completed, during a SiOCH polymer film is deposited by a plasma-enhanced CVD method. If oxidation of a thin film of the metal is not completed, during a SiOCH polymer film is deposited by a plasma-enhanced CVD method, the metal remains as metal on the copper wiring surface.

A second metal composing a second ion conductive layer 23b contains preferably the same metal as a first metal contained in a first upper electrode layer 22a and a second upper electrode layer 22b. A second metal composing a second ion conductive layer 23b is more preferably the same as a first metal contained in a first upper electrode layer 22a and a second upper electrode layer 22b. By this, when a second metal composing a second ion conductive layer 23b diffuses to a first upper electrode layer 22a or a second upper electrode layer 22b, generation of a defect in a first upper electrode layer 22a or a second upper electrode layer 22b can be prevented. If a defect is generated in a first upper electrode layer 22a or a second upper electrode layer 22b, the dielectric breakdown voltage of a first ion conductive layer 23a may decrease originating from such a defect.

A thin film of a second metal to be deposited for formation of a second ion conductive layer 23b may be deposited using a sputtering method, a laser ablation method, or a plasma-enhanced CVD method. Meanwhile, the film thickness of a second ion conductive layer 23b is desirably 50% or less of the film thickness of a first ion conductive layer 23a.

Next, a driving method of a switching element according to the first exemplary embodiment will be described referring to FIG. 3. It should be noted that a switching element according to the first exemplary embodiment is configured as a two-terminal switch.

For setting the switching element in an on-state, a positive voltage is applied to a lower electrode 21, while an upper electrode 22 (a first upper electrode layer 22a and a second upper electrode layer 22b) is in a grounded condition.

A metal of a lower electrode 21 is dissolved in the lower electrode 21 to a metal ion 25, and introduced through a second ion conductive layer 23b into a first ion conductive layer 23a. The metal ion 25 conducted through the second ion conductive layer 23b, and the first ion conductive layer 23a is precipitated on a surface of a first upper electrode layer 22a forming a metal bridge 24, and the lower electrode 21 and the first upper electrode layer 22a are connected by the precipitated metal bridge 24. When the lower electrode 21 and the first upper electrode layer 22a is electrically connected through the metal bridge 24, the switching element is put in an on-state.

Meanwhile, when the switching element is in an on-state, by grounding the upper electrode 22, applying a negative voltage to the lower electrode 21, the metal bridge 24 becomes a metal ion 25 and dissolved in the second ion conductive layer 23b and the first ion conductive layer 23a, so that a part of the metal bridge 24 is broken. On this occasion, the metal ion 25 is collected by the metal bridge 24 dispersed in the second ion conductive layer 23b, and the first ion conductive layer 23a, and the lower electrode 21. As the result, the electrical connection between the lower electrode 21 and the first upper electrode layer 22a is broken and the switching element is put in an off-state.

For switching the switching element again in an on-state, after having switched the switching element in an off-state, it is only required to ground the upper electrode 22 and apply again a positive voltage to the lower electrode 21. Further, the switching element may be switched to an on-state by applying a negative voltage to the upper electrode 22 in a state in which the lower electrode 21 is grounded, or the switching element may, be switched to an off-state by applying a positive voltage to the upper electrode 22 in a state in which the lower electrode 21 is grounded.

During a process for switching the switching element to an off-state, a change in electrical properties, such as increase of the resistance between the lower electrode 21 and the upper electrode 22, and a change of an interelectrode capacitance, occurs in a stage prior to complete electrical disconnection, and thereafter electrical connection is finally cut off.

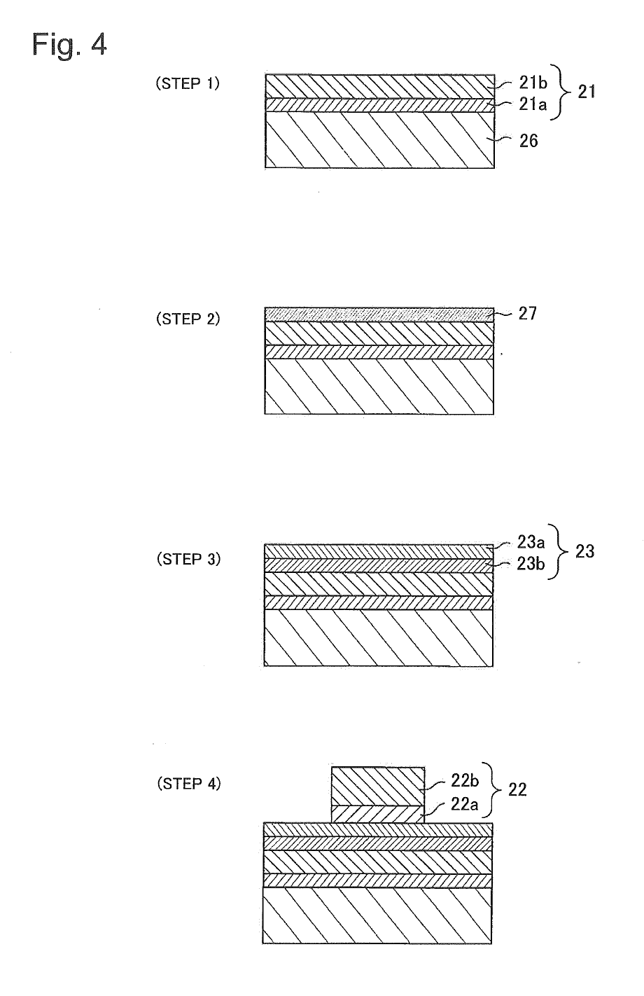

Next, a favorable method for producing a switching element according to the first exemplary embodiment will be described. FIG. 4 is cross-sectional views showing a method for producing a switching element according to the first exemplary embodiment.

### (Step 1)

On a surface of a low resistance silicon substrate 26 a tantalum film 21a with a film thickness of 20 nm is deposited by a sputtering method, and a copper film 21b with a film thickness of 100 nm is deposited on the tantalum film 21a by a sputtering method. A laminate of the tantalum film 21a and the copper film 21b is used as a lower electrode 21.

### (Step 2)

A titanium film with a film thickness of 0.5 nm, an aluminum film with a film thickness of 0.5 nm, or a laminate of a titanium film with a film thickness of 0.5 nm and an aluminum film with a film thickness of 0.5 nm is formed on the lower electrode 21 as a metallic layer 27. The metallic layer 27 is deposited, for example, by a sputtering method.

### (Step 3)

A SiOCH polymer film with a film thickness of 6.0 nm is formed by a plasma-enhanced CVD method as a first ion conductive layer 23a. The SiOCH polymer film is, for example, formed as follows. A source material for a cyclic organic siloxane, and helium as a carrier gas are supplied in a reaction chamber, and when the supply of the both is stabilized such that the reaction chamber pressure becomes constant, application of RF power is initiated. The supply rate of the source material is from 10 to 200 sccm, and with respect to helium, 500 sccm of helium is supplied through a source material vaporizer, and 500 sccm of helium is supplied directly into a reaction chamber through a separate line. In depositing the first ion conductive layer 23a the metallic layer 27 is oxidized by oxygen present in a reaction chamber, thereby forming a second ion conductive layer 23b constituted with a metal oxide film. The thus formed first ion conductive layer 23a and second ion conductive layer 23b constitute a variable resistance layer 23.

### (Step 4)

A thin film of a ruthenium alloy containing titanium with a film thickness 30 nm is formed as a first upper electrode layer 22a on the first ion conductive layer 23a by a co-sputtering method. The content of titanium in the ruthenium alloy composing the first upper electrode layer 22a is regulated, for example, to 25 atm %. Thereafter, a titanium nitride film with a film thickness of 50 nm is formed on the first upper electrode layer 22a as a second upper electrode layer 22b. The titanium content in the titanium nitride film is higher than the titanium content in a ruthenium alloy, and regulated, for example, to 50 atm %. For forming a first upper electrode layer 22a, or a second upper electrode layer 22b, a shadow mask made of a stainless steel or silicon is used, and a first upper electrode layer 22a, or a second upper electrode layer 22b with a shape corresponding to an opening provided on the shadow mask is formed. The first upper electrode layer 22a, or the second upper electrode layer 22b is formed, for example, to a square of from 30 μm to 150 μm on a side. The first upper electrode layer 22a, and the second upper electrode layer 22b constitute an upper electrode 22.

The switching element according to the first exemplary embodiment described above may be integrated in a multilayer wiring layer of a semiconductor device. The constitution of a semiconductor device, in which a switching element according to the first exemplary embodiment is integrated in a multilayer wiring layer, will be described below.

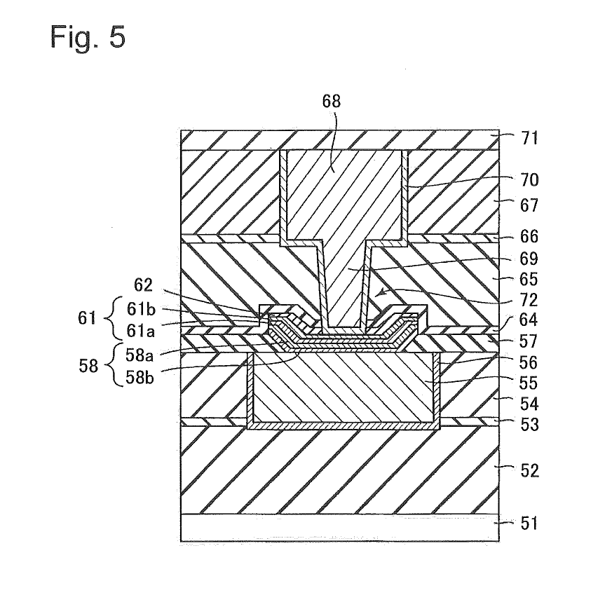

FIG. 5 is a partial cross-sectional view schematically showing the configuration of a semiconductor device integrating a switching element according to the first exemplary embodiment. A two-terminal switch 72, which is a switching element according to the first exemplary embodiment, is integrated in a multilayer wiring layer formed above a semiconductor substrate 51.

According to the first exemplary embodiment, a multilayer wiring layer has an insulation laminate. The insulation laminate is provided with an interlayer insulation film 52, a barrier insulation film 53, an interlayer insulation film 54, a barrier insulation film 57, a protection insulation film 64, an interlayer insulation film 65, an etching stopper film 66, an interlayer insulation film 67, and a barrier insulation film 71, layered upward one on another on the semiconductor substrate 51. In the multilayer wiring layer, a wiring trench is formed in the interlayer insulation film 54, and the barrier insulation film 53. The side faces and the bottom face of the wiring trench are coated with a barrier metal film 56, and a first wiring 55 is formed on the barrier metal film 56 in such a way as to fill the wiring trench. Further, a contact hole is formed in the interlayer insulation film 65, the protection insulation film 64, and a hard mask film 62, and further a wiring trench is formed in the interlayer insulation film 67, and the etching stopper film 66. The side faces and the bottom faces of the contact hole and the wiring trench are coated with a barrier metal film 70. A plug 69 is formed so as to fill the contact hole, and a second wiring 68 is formed so as to fill the wiring trench. The second wiring 68 and the plug 69 are integrated together.

In the barrier insulation film 57, an opening communicating with the first wiring 55 is formed. A second ion conductive layer 58b, a first ion conductive layer 58a, a first upper electrode layer 61a, and a second upper electrode layer 61b are layered one on another to cover a part of the first wiring 55 located inside the opening, the side face of the opening of the barrier insulation film 57, and a part of the upper surface of the barrier insulation film 57.

A two-terminal switch 72 has a configuration with a first wiring 55 to be used as a lower electrode, an upper electrode 61 provided with a first upper electrode layer 61a, and a second upper electrode layer 61b, and a variable resistance layer 58 provided with a first ion conductive layer 58a, and a second ion conductive layer 58b. More specifically, inside the opening formed in a barrier insulation film 57, a second ion conductive layer 58b and a first wiring 55 are in direct contact with each other, and a first ion conductive layer 58a and a first upper electrode layer 61a are in direct contact with each other. Further, inside the opening formed in the barrier insulation film 57, the second upper electrode layer 61b is electrically connected with a plug 69 through a barrier metal film 70. In addition, a hard mask film 62 is formed on the second upper electrode layer 22b. Furthermore, the upper face and the side faces of a laminate constituted with the second ion conductive layer 58b, the first ion conductive layer 58a, the first upper electrode layer 61a, the second upper electrode layer 61b, and the hard mask film 62 are covered with a protection insulation film 64.

Such two-terminal switch 72 configured as described above is switched to an on-state or an off-state by application of a voltage or a current. Switching of the two-terminal switch 72 is conducted, for example, utilizing electric-field diffusion of a metal ion supplied from a metal forming the first wiring 55 to the second ion conductive layer 58b and the first ion conductive layer 58a.

In this regard, by utilizing the first wiring 55 also as a lower electrode of the two-terminal switch 72, the electrode resistance can be lowered, while reducing the number of process steps. More specifically, a two-terminal switch 72 can be installed only by forming at least two photoresist mask sets as an additional step to an ordinary damascene copper wiring process, thereby achieving reduction of resistance and reduction of cost for a switching element at the same time.

The semiconductor substrate 51 is a substrate, on which a semiconductor device is formed. As the semiconductor substrate 51, for example, a silicon substrate, a single crystal substrate, a SOI (Silicon on Insulator) substrate, a TFT (Thin Film Transistor) substrate, or a substrate for producing a liquid crystal can be used.

The interlayer insulation film 52 is an insulation film formed on the semiconductor substrate 51. As the interlayer insulation film 52, for example, a silicon oxide film, or a low-dielectric constant film (for example, a SiOCH film) with a relative dielectric constant lower than a silicon oxide film can be used. The interlayer insulation film 52 may be a laminate of a plurality of insulation films.

The barrier insulation film 53 is an insulation film with a barrier property provided between the interlayer insulation films 52 and 54. The barrier insulation film 53 functions as an etching-stop layer in forming a wiring trench to be filled with the first wiring 55. As the barrier insulation film 53, for example, a silicon nitride film, a SiC film, or a silicon carbonitride film can be used. The barrier insulation film 53 may be omitted depending on a selected etching condition for the wiring trench.

The interlayer insulation film 54 is an insulation film formed on the barrier insulation film 53. As the interlayer insulation film 54, for example, a silicon oxide film, or a low-dielectric constant film (for example, a SiOCH film) with a relative dielectric constant lower than a silicon oxide film can be used. The interlayer insulation film 54 may be a laminate of a plurality of insulation films.

A wiring trench to be filled with the first wiring 55 is formed in the barrier insulation film 53 and the interlayer insulation film 54. The side faces and the bottom face of the wiring trench are coated with the barrier metal film 56, and further the first wiring 55 is formed on the barrier metal film 56 in such a way as to fill the wiring trench. The barrier insulation film 53 may be omitted subject to a selected etching condition for the wiring trench.

The first wiring 55 is wiring embedded in the wiring trench formed in the interlayer insulation film 54 and the barrier insulation film 53. The first wiring 55 is a component corresponding to the lower electrode 21 of the switching element according to FIG. 2. In other words, the first wiring 55 functions also as a lower electrode of the two-terminal switch 72 and is in direct contact with the second ion conductive layer 58b of the variable resistance layer 58. The upper surface of the second ion conductive layer 58b is in direct contact with the under surface of the first ion conductive layer 58a, and the upper surface of the first ion conductive layer 58a is in direct contact with the first upper electrode layer 61a. As a metal composing the first wiring 55, a metal, which generates a metal ion capable of diffusion or ion conduction in the variable resistance layer 58, may be used, and, for example, copper can be used. The first wiring 55 may be formed with an alloy containing a metal (for example, copper), which generates a metal ion capable of diffusion or ion conduction in the variable resistance layer 58, and aluminum.

The barrier metal film 56 is an electrically conductive film with a barrier property, which covers the side faces and the bottom face of the first wiring 55 to prevent a metal forming the first wiring 55 from diffusing into the interlayer insulation film 54 or an underlying layer. When the first wiring 55 is formed with a metal containing copper as a main component, a thin film of a refractory metal, or a nitride of a refractory metal, such as tantalum, tantalum nitride, titanium nitride, and tungsten carbonitride, or a laminate film thereof, may be used as the barrier metal film 56.

The barrier insulation film 57 is formed so as to cover the interlayer insulation film 54 and the first wiring 55. By this means, the barrier insulation film 57 prevents oxidation of a metal composing the first wiring 55 (for example, copper), prevents diffusion of a metal composing the first wiring 55 into the interlayer insulation film 65, or plays a role of an etching-stop layer in processing the upper electrode 61 and the variable resistance layer 58. For the barrier insulation film 57, for example, a SiC film, a silicon carbonitride film, a silicon nitride film, and a laminate thereof may be used. The barrier insulation film 57 uses preferably the same material as for the protection insulation film 64 and the hard mask film 62.

The first ion conductive layer 58a and the second ion conductive layer 58b constitute the variable resistance layer 58, whose resistance is changed by an action (such as diffusion and ion conduction) of a metal ion generated from a metal composing the first wiring 55 (lower electrode). The first ion conductive layer 58a and the second ion conductive layer 58b are components respectively corresponding to the first ion conductive layer 23a and the second ion conductive layer 23b of the switching element in FIG. 2.

The first ion conductive layer 58a is constituted with a film containing silicon, oxygen, and carbon as main components, such as a SiOCH polymer containing silicon, oxygen, carbon, and hydrogen (for example, a polymer of an organic silica compound such as a cyclic siloxane). A SiOCH polymer film to be used for the first ion conductive layer 58a may be deposited by a plasma-enhanced CVD (Plasma-enhanced Chemical Vapor Deposition) method. According to an exemplary embodiment, a SiOCH polymer film to be used as the first ion conductive layer 58a is formed as follows. A source material for a cyclic organic siloxane, and helium as a carrier gas are supplied in a reaction chamber, and when the supply of the both is stabilized such that the reaction chamber pressure becomes constant, application of RF power is initiated. The supply rate of the source material is from 10 to 200 sccm, and with respect to helium, 500 sccm of helium is supplied through a source material vaporizer, and 500 sccm of helium is supplied directly into a reaction chamber through a separate line

The second ion conductive layer 58b has a function to prevent diffusion of a metal composing the first wiring 55 to the first ion conductive layer 58a due to heating or plasma during deposition of the first ion conductive layer 58a. Further, the second ion conductive layer 58b has a function to prevent promotion of diffusion due to oxidation of the first wiring 55 used as a lower electrode.

A thin film of a metal composing the second ion conductive layer 58b is oxidized to form a thin film of a metal oxide during deposition of the first ion conductive layer 58a, thereby constituting a part of the variable resistance layer 58. As a thin film of a metal composing the second ion conductive layer 58b, for example, thin films of titanium, aluminum, zirconium, hafnium, and tantalum are conceivable. Such thin films of a metal are oxidized during deposition of the first ion conductive layer 58a to form thin films of titanium oxide, aluminum oxide, zirconium oxide, hafnium oxide, and tantalum oxide, thereby constituting a part of the variable resistance layer 58.

The optimum film thickness of a metal film constituting the second ion conductive layer 58b is from 0.5 to 1 nm. When the metal film is thinner, slight oxidation of a surface of the first wiring 55 occurs, and when the same is thicker, it is not oxidized completely during formation of the first ion conductive layer 58a and remains as metal.

The variable resistance layer 58 is formed such that it covers a part of the upper surface of the first wiring 55, a tapered surface of the opening of the barrier insulation film 57, and a part of the upper surface of the barrier insulation film 57. The variable resistance layer 58 is placed such that a circumferential part of a junction between the first wiring 55 and the variable resistance layer 58 is located at least along the tapered surface of the opening portion of the barrier insulation film 57.

A metal film to be used for forming the second ion conductive layer 58b may be formed as a laminated film, or formed as a monolayer film. A second metal composing the second ion conductive layer 58b contains preferably the same metal as a first metal composing first upper electrode layer 61a and the second upper electrode layer 61b as described below. By this means, when the second metal composing the second ion conductive layer 58b diffuses into the first upper electrode layer 61a and the second upper electrode layer 61b, generation of a defect in the first upper electrode layer 61a and the second upper electrode layer 61b can be prevented. When a defect is generated in the first upper electrode layer 61a and the second upper electrode layer 61b, the defect may decrease the dielectric breakdown voltage of the variable resistance layer 58 as a starting point.

As described above, the first upper electrode layer 61a and the second upper electrode layer 61b constitute the upper electrode 61 of the two-terminal switch 72. The first upper electrode layer 61a and the second upper electrode layer 61b are components respectively corresponding to the first upper electrode layer 22a and the second upper electrode layer 22b of the switching element in FIG. 2.

The first upper electrode layer 61a is a lower electrode layer of the upper electrode 61, and is in direct contact with the first ion conductive layer 58a. The first upper electrode layer 61a is preferably made of an alloy of ruthenium and a first metal, namely a ruthenium alloy to which a first metal is added. The content of ruthenium in the ruthenium alloy is desirably in a range from 60 atm % or more to 90 atm % or less.

As a first metal to be added to a ruthenium alloy forming the first upper electrode layer 61a, it is desirable to select a metal, whose standard Gibbs energy of formation with respect to an oxidation process (a process for forming a metal ion from a metal) is larger than ruthenium in the negative direction. With respect to titanium, tantalum, zirconium, hafnium, and aluminum, for which the standard Gibbs energy of formation with respect to an oxidation process is larger than ruthenium in the negative direction, a spontaneous chemical reaction occurs more easily compared to ruthenium, and therefore the reactivity is high. Consequently, when a ruthenium alloy composing the first upper electrode layer 61a contains a first metal as listed above, the adherence to a metal bridge formed with a metal composing the first wiring 55 is improved. That is, a first metal to be contained in a ruthenium alloy composing the first upper electrode layer 61a is preferably at least one metal selected from the group consisting of titanium, tantalum, zirconium, hafnium, and aluminum. On the other hand, when the first upper electrode layer 61a is composed only of a first metal without containing ruthenium, the reactivity becomes too high, and a transit to an off-state becomes impossible.

A transit from an on-state to an off-state proceeds by an oxidation reaction (dissolving reaction) of a metal bridge. When the standard Gibbs energy of formation with respect to an oxidation process of a metal composing the first upper electrode layer 61a is larger in the negative direction than that of a metal composing the first wiring 55, the following phenomenon occurs. In other words, it is a phenomenon that a transit to an off-state becomes impossible, because an oxidation reaction of the first upper electrode layer 61a proceeds more than an oxidation reaction of a metal bridge formed with a metal composing the first wiring 55.

Therefore, as a metal material composing the first upper electrode layer 61a, an alloy of ruthenium and a first metal with a standard Gibbs energy of formation with respect to an oxidation process smaller than copper in the negative direction is preferable. Further, if copper, which is a component of a metal bridge, gets mixed in the first upper electrode layer 61a, the effect of addition of a metal with a standard Gibbs energy large in the negative direction is weakened, and therefore a first metal to be added to a ruthenium alloy is preferably a material having a barrier property against copper and a copper ion. Examples of such a metal include tantalum, titanium, and aluminum.

Meanwhile, it has been known that the larger the amount of a first metal is, the more stable an on-state becomes, and that the stability is also improved by addition of 5 atm %. Especially, when titanium is used as the first metal, it is superior in transit to an off-state and stability in an on-state. Specifically, it is preferable that the first upper electrode layer 61a is formed with a ruthenium alloy containing titanium, and the titanium content in the ruthenium alloy is regulated within a range from 20 atm % or more to 30 atm % or less.

For forming the first upper electrode layer 61a, use of a sputtering method is desirable. For forming an alloy into a film by a sputtering method, there are a method, by which a target of an alloy of ruthenium and a first metal is used, and a co-sputtering method, by which sputtering is conducted simultaneously with a target of ruthenium and a target of a first metal in the same chamber. Moreover, for forming an alloy into a film by a sputtering method, there is an intermixing method, by which a thin film of a first metal is formed in advance, and ruthenium is deposited thereon using a sputtering method, during which an alloy is formed by the energy of colliding atoms. By using a co-sputtering method or an intermixing method, the composition of an alloy can be modulated appropriately. When an intermixing method is applied, it is preferable to conduct a heat treatment at 400° C. or less for homogenizing the mixture condition after completing deposition of a ruthenium film.

The second upper electrode layer 61b is an upper electrode layer of the upper electrode 61 and formed on the first upper electrode layer 61a. The second upper electrode layer 61b has a function to protect the first upper electrode layer 61a. That is, through protection of the first upper electrode layer 61a by the second upper electrode layer 61b, a damage to the first upper electrode layer 61a in a production process can be suppressed so as to keep a switching characteristic of the two-terminal switch 72.

The second upper electrode layer 61b is composed of a nitride of a first metal contained in a ruthenium alloy composing the first upper electrode layer 61a. It is also favorable that a first metal is selected from the group consisting of titanium, tantalum, zirconium, hafnium, and aluminum, as described above, from the point that a nitride of a first metal composing the second upper electrode layer 61b comes to have electrical conductivity. Additionally, the etching speed of a nitride of a first metal composing the second upper electrode layer 61b becomes low with respect to plasma of a fluorocarbon gas to be used for etching the interlayer insulation film 65. This low etching speed is convenient also for the second upper electrode layer 61b to function as an etching-stop film.

When a metal other than a nitride is used for the second upper electrode layer 61b, a part of the metal diffuses into the first upper electrode layer 61a due to heating or plasma damage in a process. By the diffusion of the metal into the first upper electrode layer 61a, defects may appear in the first upper electrode layer 61a and the dielectric breakdown voltage of an ion conductive layer may possibly decrease originating from such defects. When a metal nitride, which is stable and a compound having favorable electrical conductivity, is used in the second upper electrode layer 61b, diffusion of the metal into the first upper electrode layer 61a can be prevented. Especially, when a metal of a nitride composing the second upper electrode layer 61b and a first metal contained in a ruthenium alloy composing the first upper electrode layer 61a are identical, it is preferable in that occurrence of a defect due to diffusion of the first metal contained in a ruthenium alloy can be prevented more efficiently.

When the first upper electrode layer 61a is formed, for example, with a ruthenium alloy containing titanium, the second upper electrode layer 61b is preferably formed with titanium nitride. Further, when the first upper electrode layer 61a is formed with a ruthenium alloy containing tantalum, the second upper electrode layer 61b is preferably formed with tantalum nitride. When the metal components composing the first upper electrode layer 61a and the second upper electrode layer 61b are selected to be the same, even if a metal of the second upper electrode layer 61b diffuses into the first upper electrode layer 61a, a defect is hardly formed.

In this case, the content of a first metal contained in a nitride composing the second upper electrode layer 61b is selected larger than the content of a first metal contained in a ruthenium alloy composing the first upper electrode layer 61a. By this means, diffusion of a metal composing the first upper electrode layer 61a into a nitride composing the second upper electrode layer 61b to change the composition of a ruthenium alloy composing the first upper electrode layer 61a can be prevented.

Specifically, when the second upper electrode layer 61b is formed with titanium nitride, the content of titanium in the second upper electrode layer 61b may be in a range from 40 atm % or more to 80 atm % or less, and especially the composition of from 40 atm % or more to 50 atm % is preferable. In case of 40 atm % or less, there is a risk that titanium in the first upper electrode layer 61a may diffuse into the second upper electrode layer 61b. Further, in case of 50 atm % or more, not only TiN, which is a composition of a stable titanium nitride to be used for a metal electrode, but also a crystal phase attributable to Ti₂N are detectable by an X-ray diffraction analysis. Since presence of Ti₂N promotes oxidation, it is possible that the second upper electrode 61b is oxidized, for example, during formation of a hard mask film 62. If the second upper electrode 61b is oxidized, the specific resistance of the second upper electrode 61b increases, so that the parasitic resistance of the two-terminal switch 72 increases also.

For forming the second upper electrode layer 61b, use of a sputtering method is desirable. For forming a film of a metal nitride using a sputtering method, use of a reactive sputtering method, by which a metal target is evaporated using plasma of a mixture gas of nitrogen and argon, is preferable. A metal evaporated from a metal target reacts with nitrogen to form a metal nitride and then is deposited on a substrate.

As a more preferable method for forming the second upper electrode layer 61b, use of co-sputtering with both a ruthenium target electrode and a target electrode made of a first metal is preferable. When an alloy target composed of ruthenium and a first metal is used, since the respective sputtering yields of the materials are different, the composition shifts over continuous use, and therefore the composition of a film to be formed can be hardly controlled precisely. On the other hand, in the case of a co-sputtering method, the composition of a film to be formed can be controlled precisely by setting in advance an individual electric power to be applied to each target electrode. Such a technique is especially effective, in a case in which titanium or tantalum is used as a first metal.

The hard mask film 62 is used as a mask for etching the second upper electrode layer 61b, the first upper electrode layer 61a, the first ion conductive layer 58a, and the second ion conductive layer 58b, and used also as a passivation film. As the hard mask film 62, for example, a silicon nitride film, and a silicon carbonitride film can be used. The material for the hard mask film 62 is preferably identical with that for the protection insulation film 64, and the barrier insulation film 57. In this way, the surroundings of the two-terminal switch 72 are occupied entirely with components made of an identical material so that material interfaces are integrated and entry of moisture, etc. from the outside can be prevented, and detachment of the material from the two-terminal switch 72 itself can be prevented.

The protection insulation film 64 is an insulation film having functions to prevent infliction of a damage on the two-terminal switch 72, and to prevent elimination of oxygen from the first ion conductive layer 58a. As the protection insulation film 64, for example, a silicon nitride film, and a silicon carbonitride film can be used. The protection insulation film 64 uses preferably the same material as the hard mask film 62 and the barrier insulation film 57. In the case of the same material, the protection insulation film 64 is integrated with the barrier insulation film 57 and the hard mask film 62, so that the adherence between interfaces is improved, and the two-terminal switch 72 can be better protected.

The interlayer insulation film 65 is an insulation film formed on the protection insulation film 64. As the interlayer insulation film 65, for example, a silicon oxide film, a SiOC film, and a low-dielectric constant film with a relative dielectric constant lower than a silicon oxide film (for example, a SiOCH film) can be used. The interlayer insulation film 65 may be a laminate of a plurality of insulation films. The interlayer insulation film 65 may use the same material as the interlayer insulation film 67. In the interlayer insulation film 65, a contact hole for filling a plug 69 is formed. The contact hole is coated with the barrier metal film 70, and the plug 69 is formed on the barrier metal film 70 so as to fill the contact hole.

The etching stopper film 66 is an insulation film provided between the interlayer insulation films 65 and 67. The etching stopper film 66 functions as an etching-stop layer, when a wiring trench for embedding the second wiring 68 is processed. As the etching stopper film 66, for example, a silicon nitride film, a SiC film, and a silicon carbonitride film may be used.

The interlayer insulation film 67 is an insulation film formed on the etching stopper film 66. As the interlayer insulation film 67, for example, a silicon oxide film, a SiOC film, and a low-dielectric constant film with a relative dielectric constant lower than a silicon oxide film (for example, a SiOCH film) can be used. The interlayer insulation film 67 may be a laminate of a plurality of insulation films. The interlayer insulation film 67 may use the same material as the interlayer insulation film 65.

A wiring trench for embedding a second wiring 68 is formed in the etching stopper film 66 and the interlayer insulation film 67. The side faces and the bottom face of the wiring trench are coated with the barrier metal film 70, and a second wiring 68 is formed on the barrier metal film 70 so as to fill the wiring trench. The etching stopper film 66 may be eliminated subject to a selected etching condition of the wiring trench.

The second wiring 68 is wiring embedded in a wiring trench formed in the interlayer insulation film 67 and the etching stopper film 66. The second wiring 68 is integrated with the plug 69. The plug 69 is embedded in a contact hole formed through the interlayer insulation film 65, the protection insulation film 64, and the hard mask film 62. The plug 69 is electrically connected with the second upper electrode layer 61b through the barrier metal film 70. For example, copper may be used for the second wiring 68 and the plug 69.

The barrier metal film 70 is an electrically conductive film having a barrier property and covers the side faces and the bottom faces of the second wiring 68 and the plug 69 to prevent a metal forming the second wiring 68 and the plug 69 from diffusing to the interlayer insulation films 65 and 67 or an underlying layer. When the second wiring 68 and the plug 69 are made of metal elements including copper as a main component, a refractory metal, a nitride of a refractory metal, or a laminated film thereof may be used as the barrier metal film 70. As such a refractory metal, a nitride of a refractory metal, or a laminated film thereof, a refractory metal, or a nitride of a refractory metal, such as tantalum, tantalum nitride, titanium nitride, and tungsten carbonitride, or a laminated film thereof are conceivable. A part of the barrier metal film 70, which contacts at least the second upper electrode layer 61b, is preferably made of the same material as the second upper electrode layer 61b. When, for example, the barrier metal film 70 is constituted with a laminate of a lower layer formed with tantalum nitride and an upper layer formed with tantalum, tantalum nitride, which is the material for the lower layer, is preferably used for the second upper electrode layer 61b.

The barrier insulation film 71 is formed so as to cover the second wiring 68 and the interlayer insulation film 67, and is an insulation film having functions of preventing a metal (for example, copper) to form the second wiring 68 from oxidation, and preventing the metal to form the second wiring 68 from diffusing to an upper layer. As the barrier insulation film 71, for example, a silicon carbonitride film, a silicon nitride film, and a laminate thereof may be used.

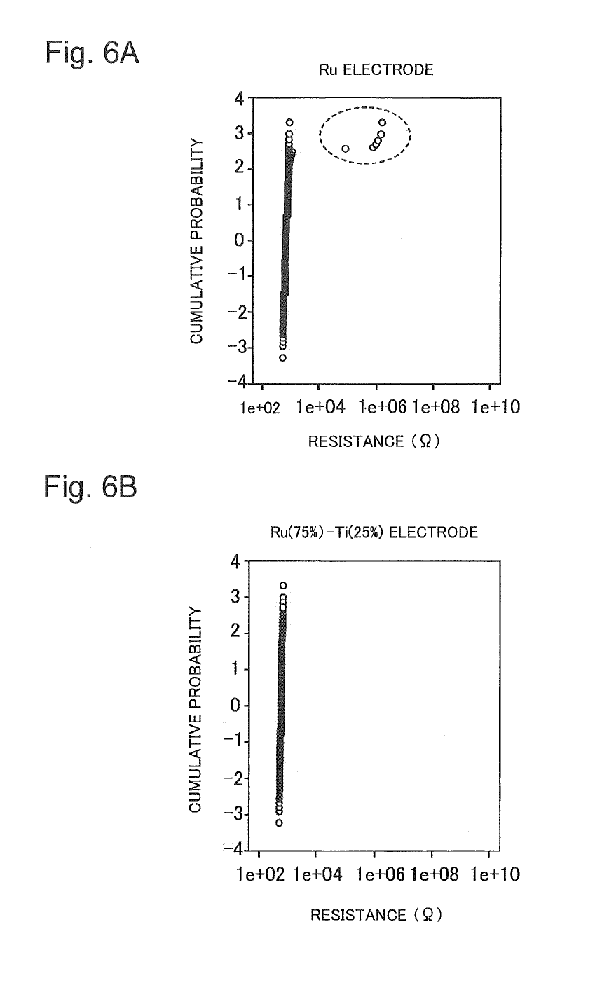

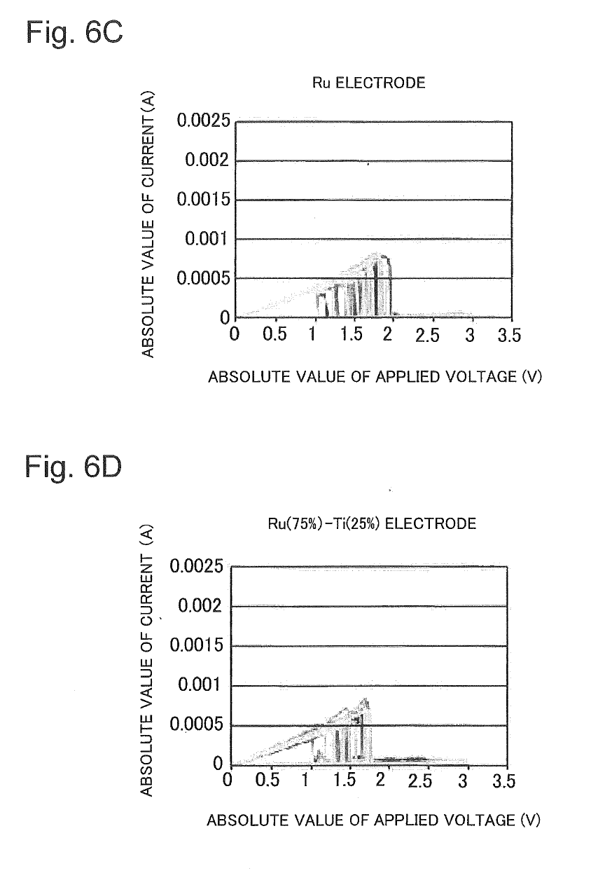

Next, the action of a switching element according to the first exemplary embodiment, especially characteristics of a switching element provided with the first upper electrode layer 61a formed with a ruthenium alloy containing a first metal (for example, titanium) will be described referring to FIG. 6A to FIG. 6E. FIG. 6A and FIG. 6B are graphs, in which two normal distributions of current values with respect to a switching element integrated in a multilayer wiring as shown in FIG. 5 immediately after switching to an on-state and after the elapse of 100 hours are superimposed. The distribution of the resistance values of a semiconductor or a variable resistance element is generally plotted as a normal distribution. A value being off a normal distribution indicates an abnormal state such as a failure, and for discriminating such an event a normal probability plot is broadly used as a plotting method. In general, linearity on a normal probability plot indicates a normal distribution, the part surrounded by a dotted line in FIG. 6A is not on a normal distribution to indicate abnormality (failure). “Cumulative probability” on the ordinate of FIG. 6A, or FIG. 6B signifies more accurately “multiple of standard deviation” or “difference of standard deviation from an average”. It corresponds to a position, which is apart from an average value (a value with maximum frequency, ordinarily 50%) by a standard deviation on the abscissa of a so-called histogram. The scale unit of the ordinate “cumulative probability” of FIG. 6A, or FIG. 6B means “multiple of standard deviation” or “difference of standard deviation from an average” in a case the average value of measured current values is assumed to be scale unit “0”. Expressing the value in terms of probability is used for reliability evaluation as “cumulative failure probability”. All switching elements are integrated as a 4 kilobit array (4,096 elements), and current values are measured for all switching elements in the array. They are all plotted with open circles “∘”, and it can be known that there is no change in resistance value, where the normal distribution of current values immediately after switching to an on-state, and the normal distribution of current values after the elapse of 100 hours are overlapped. In switching to an on-state, a positive voltage is applied to the first wiring 55 (lower electrode) in FIG. 5.

FIG. 6A shows measurement results of current values on a switching element provided with the first upper electrode layer 61a formed solely with ruthenium, and FIG. 6B shows measurement results of current values on a switching element provided with the first upper electrode layer 61a formed with a ruthenium alloy containing titanium. The “ruthenium alloy containing titanium” composing the first upper electrode layer 61a of the switching element used for measurement in FIG. 6B is known by X-ray photoelectron spectroscopy to have a composition of 75 atm % of ruthenium, and 25 atm % of titanium. As shown in FIG. 6A, with respect to the array of switching elements provided with the first upper electrode layer 61a formed with ruthenium, after 100 hours 6 switching elements have come to have high resistance (a plot surrounded by a dotted line). Meanwhile, as shown in FIG. 6B, with respect to the array of switching elements provided with the first upper electrode layer 61a formed with a ruthenium alloy containing titanium, there was no switching element that came to have high resistance after 100 hours.

Meanwhile, FIG. 6C and FIG. 6D show current-voltage characteristics during a transit from an on-state to an off-state with respect to a switching element formed in multilayer wiring. In switching from an on-state to an off-state, a negative voltage is applied to the first wiring 55 (lower electrode) in FIG. 5. Although a current found during measurement of current-voltage characteristics is a negative current, both current and voltage are expressed in terms of absolute values in FIG. 6C and FIG. 6D.

FIG. 6C shows measurement results concerning current-voltage characteristics of a switching element provided with the first upper electrode layer 61a formed solely with ruthenium. FIG. 6D shows measurement results concerning current-voltage characteristics of a switching element provided with the first upper electrode layer 61a formed with a ruthenium alloy containing titanium. The “ruthenium alloy containing titanium” composing the first upper electrode layer 61a of the switching element used for measurement in FIG. 6D is known by X-ray photoelectron spectroscopy to have a composition of 75 atm % of ruthenium, and 25 atm % of titanium.

Each curve in FIG. 6C or FIG. 6D shows a current voltage curve of each single device in resetting under the conditions in FIG. 6C or FIG. 6D. When the holding ability in an on-state is enhanced, the stability of an on-state increases, and therefore there is a concern that a current required for a transit to an off-state (reset) may increase. As shown in FIG. 6C and FIG. 6D, the resistance values during a transit to an on-state are almost the same with respect to a switching element provided with the first upper electrode layer 61a formed solely with ruthenium, and to a switching element provided with the first upper electrode layer 61a formed with a ruthenium alloy containing titanium. In both FIG. 6C and FIG. 6D, the absolute value of the maximum current is a current required for a transit from an on-state to an off-state, which is almost the same between FIG. 6C and FIG. 6D. The apex of the plotted triangle in FIG. 6C or FIG. 6D (near 2 V to 2.5 V) shows the maximum current in resetting. In FIG. 6C and FIG. 6D the values are almost the same. As obvious from the above, an exemplary embodiment according to the present invention offers an advantage that the holding ability of an on-state is increased without increasing the reset current. Further, even by using the first upper electrode layer 61a formed with a “ruthenium alloy containing titanium”, the current in transiting from an on-state to an off-state does not increase. A “ruthenium alloy containing titanium” exhibits a higher resistivity compared to ruthenium only. Therefore, it is believed that the upper electrode 61 would be easily heated up by the current in transiting from an on-state to an off-state. The contribution of Joules heat generated in a metal bridge is important for a dissolving reaction of a metal bridge formed in the first ion conductive layer 58a to proceed by voltage application.

In this regard, a reason behind such high holding ability without increase in a current in transiting from an on-state to an off-state is conceivably attributable to an effect that Joules heat generated in a metal bridge is confined by heating of the first upper electrode layer 61a due to a current in transiting from an on-state to an off-state. The confining effect of Joules heat is obtained from forming the first upper electrode layer 61a with a ruthenium alloy such as a “ruthenium alloy containing titanium”.

Performances equivalent to the holding ability characteristics and electrical properties of a switching element in which the first upper electrode layer 61a is formed with a ruthenium alloy containing titanium as shown in FIG. 6B and FIG. 6D were also observed in a case in which a ruthenium alloy containing tantalum was used. In this case, the composition of a ruthenium alloy containing titanium is 75 atm % of ruthenium, and 25 atm % of titanium, and the composition of a ruthenium alloy containing tantalum is 70 atm % of ruthenium, and 30 atm % of tantalum.

On the other hand, when the first upper electrode layer 61a is formed solely with a metal having a small standard Gibbs energy of formation with respect to an oxidation process without containing ruthenium, dielectric breakdown in the first ion conductive layer 58a occurs, if a negative voltage is applied to the first wiring 55 (lower electrode) in transiting from an on-state to an off-state. When dielectric breakdown in the first ion conductive layer 58a occurs, a switching element does not transit to an off-state. The above oxidation process is a process for forming a metal ion from a metal.

Further, also when the content of ruthenium is 30 atm % or less, breakdown in the first ion conductive layer 58a is similarly observed, if a negative voltage is applied to the first wiring 55 in transiting from an on-state to an off-state, and a switching element does not transit to an off-state.

Further, in a case in which an alloy composed of 25 atm % of ruthenium, and 75 atm % of titanium is used for the first upper electrode layer 61a, it was observed that a switching element did not transit to an off-state. Further, in a case in which an alloy composed of 30 atm % of ruthenium, and 70 atm % of tantalum is used for the first upper electrode layer 61a, it was observed that a switching element did not transit to an off-state.

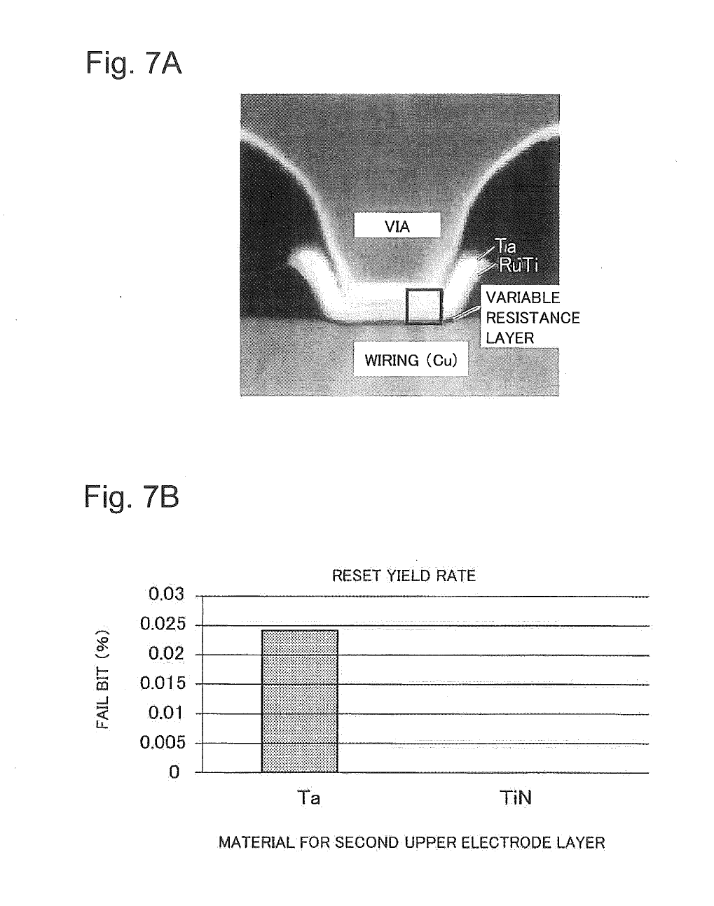

FIG. 7A shows a TEM (Transmission Electron Microscope) cross-sectional image of a device having caused a trouble in transiting to an off-state among switching elements using tantalum, which is not a nitride, for the second upper electrode layer 61b. It is understood from the TEM cross-sectional image that a part of tantalum as the second upper electrode layer 61b has diffused in an alloy of ruthenium and titanium as the first upper electrode layer 61a. If such a diffusion progresses, a defect appears in the first upper electrode layer 61a and dielectric breakdown of the variable resistance layer 58 occurs originating from the defect at a low voltage.

FIG. 7B is a graph showing the reset yield rate of a switching element according to the first exemplary embodiment. FIG. 7B shows dependence of the reset yield rate on the material for the second upper electrode layer 61b. The ordinate of the graph indicates a percentage of devices that are unable to be reset (fail bit) by a reset action, as an index of the reset yield rate. When titanium nitride is used for the second upper electrode layer 61b, the reset yield rate showing the transit probability to an offset state is enhance compared to a case where tantalum is used for the second upper electrode layer 61b. From this result, it can be understood that diffusion of a metal to the first upper electrode layer 61a is suppressed by using titanium nitride so as to enhance the dielectric breakdown voltage. The on and off repeat resistance (cycle characteristics) of a switching element is improved, conceivably because the probability of occurrence of defect of freezing to a low resistance state in a transition process to an off is decreased through improvement of the reset yield owing to suppression of dielectric breakdown.

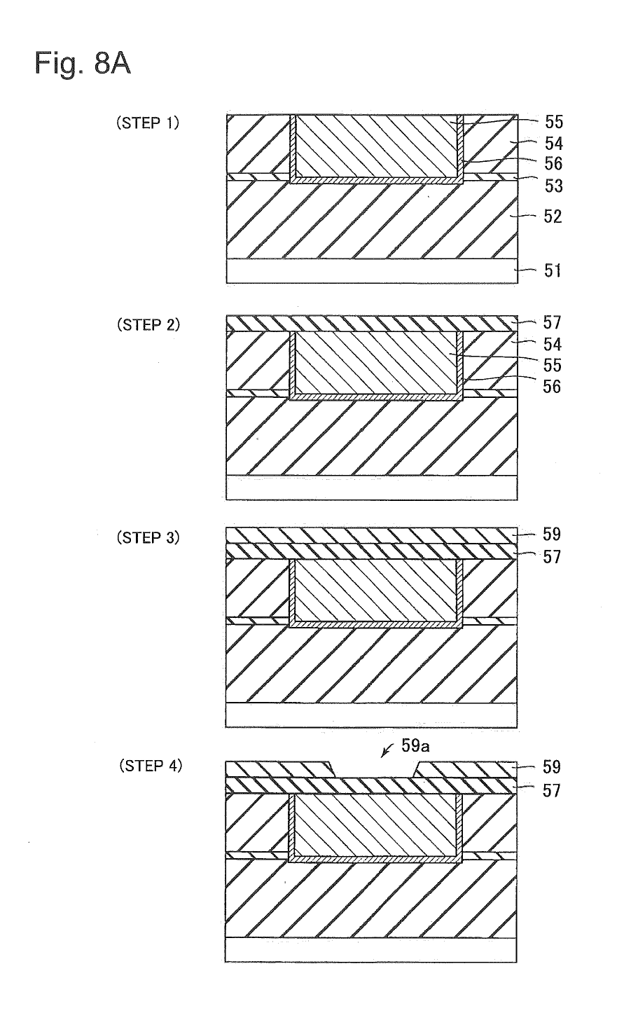

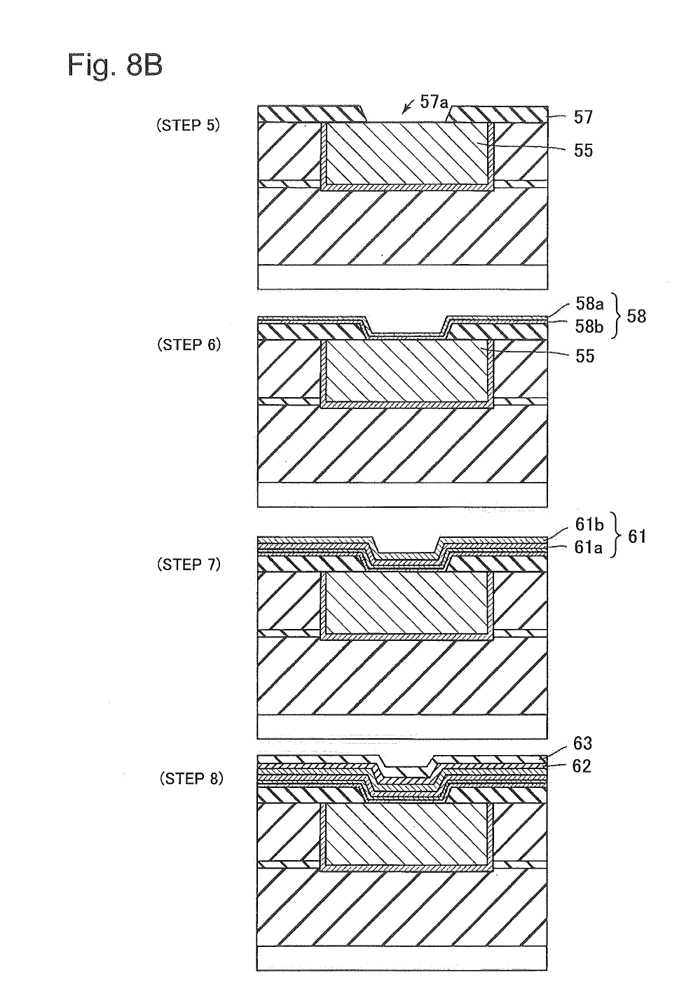

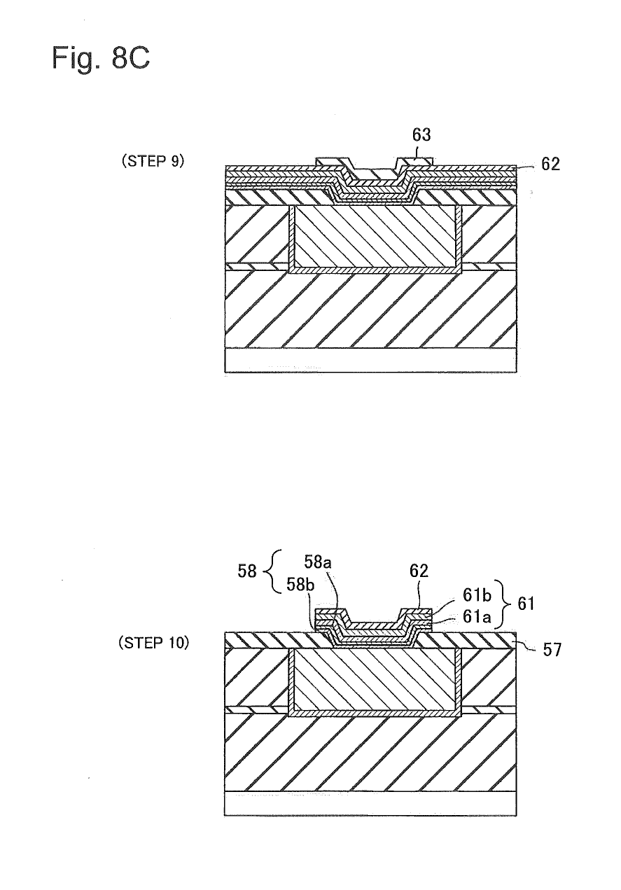

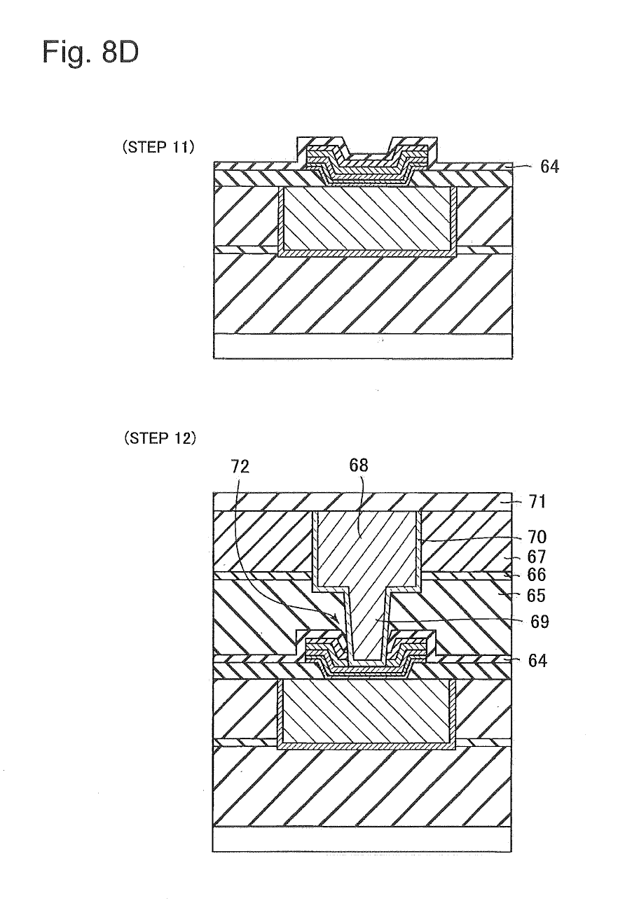

FIG. 8A to FIG. 8D are cross-sectional views schematically showing an example of a method for producing a semiconductor device integrating a switching element according to the first exemplary embodiment in a multilayer wiring layer as illustrated in FIG. 5.

### (Step 1)

As shown in FIG. 8A, the interlayer insulation film 52 is deposited on the semiconductor substrate 51, and further the barrier insulation film 53 is deposited on the interlayer insulation film 52. In this regard, the semiconductor substrate 51 is, for example, a substrate on which a semiconductor device is formed. Further, the interlayer insulation film 52 is, for example, a silicon oxide film with a film thickness of 300 nm. Further, the barrier insulation film 53 is, for example, a silicon nitride film with a film thickness of 50 nm.

Then, the interlayer insulation film 54 is deposited on the barrier insulation film 53, and thereafter a wiring trench is formed using a lithography method (including photoresist formation, dry etching, and photoresist removal) in the interlayer insulation film 54, and the barrier insulation film 53. The interlayer insulation film 54 is, for example, a silicon oxide film with a film thickness of 300 nm. The wiring trench is coated with the barrier metal film 56 (for example, a laminate of a tantalum nitride film with a film thickness of 5 nm and a tantalum film with a film thickness of 5 nm), and the first wiring 55 (for example, copper wiring) is formed on the barrier metal film 56 so as to fill the wiring trench. In Step 1, the interlayer insulation films 52 and 54 may be formed by a plasma-enhanced CVD method.

The first wiring 55 can be formed according to the following series of wiring formation procedures. For example, the barrier metal film 56 is formed by a PVD (Physical Vapor Deposition) method, and further a copper seed is formed by a PVD method. After formation of the copper seed, a copper film is formed by an electrolytic plating method so as to fill the wiring trench. Then, after a heat treatment at a temperature of 200° C. or higher, a surplus copper film outside the wiring trench is removed by a CMP (Chemical Mechanical Polishing) method, thereby completing the first wiring 55.

For the series of copper wiring formation procedures, a common technique in the art may be used. In this regard, a CMP method means a method, by which the roughness of a wafer surface to be generated during a multilayer wiring forming process is polished for planarization through contact with a rotating polishing pad while flowing a polishing liquid over the wafer surface. By polishing a surplus copper film embedded in the trench, an embedded wiring (damascene wiring) is formed. Further, the interlayer insulation film 54 is planarized by polishing.

### (Step 2)

The barrier insulation film 57 (for example, a silicon nitride film or a silicon carbonitride film with a film thickness of 50 nm) is formed so as to cover the first wiring 55 and the interlayer insulation film 54. In this regard, the barrier insulation film 57 may be formed by a plasma-enhanced CVD method. The film thickness of the barrier insulation film 57 is preferably approximately from 10 nm to 50 nm.

### (Step 3)

The hard mask film 59 (for example, a silicon oxide film) is formed on the barrier insulation film 57. In this case, the hard mask film 59, which may be an insulation film or an electro-conductive film, preferably uses a material different from that for the barrier insulation film 57 from a viewpoint of keeping the etching selection ratio in a dry etching process high. As the hard mask film 59, for example, a silicon oxide film, a silicon nitride film, a titanium nitride film, a titanium film, a tantalum film, and a tantalum nitride film may be used. Further as the hard mask film 59, a laminate of a silicon nitride film and a silicon oxide film may be also used.

### (Step 4)

The opening 59a is formed in the hard mask film 59 by forming a photoresist pattern (not illustrated) with an opening formed over the hard mask film 59, and performing dry etching using the photoresist pattern as a mask. Thereafter the photoresist pattern is eliminated by oxygen plasma ashing, etc. In this case dry etching is not always required to stop at the upper surface of the barrier insulation film 57 but a part of the barrier insulation film 57 may be etched.

### (Step 5)

The opening 57a is formed in the barrier insulation film 57 as shown in FIG. 8B by etching-back (dry etching) the barrier insulation film 57 exposed through the opening 59a of the hard mask film 59 using the hard mask film 59 as a mask. In the opening 57a of the barrier insulation film 57, a part of the first wiring 55 comes to be exposed. Then, by conducting an organic peeling treatment with an amine type pealing liquid, etc., copper oxide formed on the exposed surface of the first wiring 55 is removed, and an etching product generated during etch-back is removed. At etch-back of the barrier insulation film 57, the side face of the opening 57a of the barrier insulation film 57 can be formed as a tapered surface by applying reactive dry etching. For reactive dry etching, a gas containing fluorocarbon may be used as an etching gas. The hard mask film 59 is preferably removed completely during etch-back, however, if it is made of an insulating material, it may remain as it is. FIG. 8B shows a structure in which the hard mask film 59 is completely removed. The shape of the opening 57a of the barrier insulation film 57 may be circle, and the diameter thereof may be from 30 nm to 500 nm. Further, an oxide on the surface of the first wiring 55 is moved by RF (radio frequency) etching using a non-reactive gas. As the non-reactive gas, helium or argon may be used.

### (Step 6)

The variable resistance layer 58 provided with the first ion conductive layer 58a and the second ion conductive layer 58b is formed. Specifically, a titanium film with a film thickness of 0.5 nm and an aluminum film with a film thickness of 0.5 nm are deposited in the mentioned order forming a metal film with a total film thickness of 1 nm, so as to cover the first wiring 55 and the barrier insulation film 57. The titanium film and the aluminum film can be formed by a PVD method or a CVD method.

A SiOCH polymer film with a film thickness of 6 nm is formed by a plasma-enhanced CVD as the first ion conductive layer 58a. According to the present exemplary embodiment, a SiOCH polymer film to be used as the first ion conductive layer 58a is formed as follows. A source material for a cyclic organic siloxane, and helium as a carrier gas are supplied in a reaction chamber, and when the supply of the both is stabilized such that the reaction chamber pressure becomes constant, application of RF power is initiated. The supply rate of the source material is from 10 to 200 sccm, and with respect to helium, 500 sccm of helium is supplied through a source material vaporizer, and 500 sccm of helium is supplied directly into a reaction chamber through a separate line

A titanium film and an aluminum film are auto-oxidized by exposure to a source material for a SiOCH polymer film containing oxygen during formation of the first ion conductive layer 58a. The second ion conductive layer 58b constituting a part of the variable resistance layer 58 is formed by oxidation of the titanium film and the aluminum film.

Since moisture, etc. sticks to the opening 57a of the barrier insulation film 57 by an organic peeling treatment, degassing is preferably conducted by a heat treatment at a temperature of approximately from 250° C. to 350° C. under reduced pressure prior to formation of the variable resistance layer 58.

### (Step 7)

A thin film of a ruthenium alloy containing titanium with a film thickness of 10 nm is formed on the variable resistance layer 58 by a co-sputtering method as the first upper electrode layer 61a. In this case, a ruthenium target and a titanium target are present in the same chamber, and by sputtering at the same time a ruthenium alloy film is deposited. In depositing the ruthenium alloy film, the content of ruthenium in the ruthenium alloy containing titanium can be controlled to a desired value by regulating the application power to the ruthenium target and the application power to the titanium target. In an inventor's experimental system, the ruthenium content in the “ruthenium alloy containing titanium” could be controlled to 75 atm %, and the titanium content therein to 25 atm % by regulating the application power to the ruthenium target at 150 W, and the application power to the titanium target at 50 W.

Further, the second upper electrode layer 61b is formed on the first upper electrode layer 61a. The first upper electrode layer 61a and the second upper electrode layer 61b constitute the upper electrode 61. As the second upper electrode layer 61b, for example, a titanium nitride film with a film thickness of 25 nm is formed by a reactive sputtering method. In forming a titanium nitride film by a reactive sputtering method, a nitrogen gas and an argon gas are introduced in a chamber. In this case, by regulating the application power to a titanium target, and the ratio of the nitrogen gas to the argon gas supplied to the chamber, the titanium content in the titanium nitride film can be adjusted. In an inventors' experimental system, the titanium content in the titanium nitride film could be adjusted to 50 atm % by setting the application power to a titanium target at 600 W, and the ratio of the flow rate of the nitrogen gas to the flow rate of the argon gas at 2:1.

### (Step 8)

The hard mask film 62 (for example, a silicon nitride film or a silicon carbonitride film with a film thickness of 30 nm), and the hard mask film 63 (for example, a silicon oxide film with a film thickness of 90 nm) are layered on the second upper electrode layer 61b in the mentioned order. The hard mask films 62 and 63 may be formed using a plasma-enhanced CVD method. The hard mask films 62 and 63 may be formed using a plasma-enhanced CVD method common in the technical field. The hard mask films 62 and 63 are preferably films formed with different materials, and, for example, the hard mask film 62 may be formed with a silicon nitride film, and the hard mask film 63 may be formed with a silicon oxide film. In this case, the hard mask film 62 is preferably made of the same material as for the protection insulation film 64 described below and the barrier insulation film 57. That is, by placing the same material to surround entirely a switching element, interfaces of components surrounding the switching element are integrated, so that entry of moisture or the like from the outside can be prevented, and detachment of a material from the switching element can be prevented. Further, for the hard mask film 62, use of a high density silicon nitride film formed by using a SiH₄/N₂ mixture gas as a source material and generating high density plasma is preferable.

### (Step 9)

Next, a photoresist pattern (not illustrated) for patterning the first ion conductive layer 58a, the second ion conductive layer 58b, the first upper electrode layer 61a, and the second upper electrode layer 61b is formed on the hard mask film 63. Thereafter, as shown in FIG. 8C, the hard mask film 63 is etched by dry etching using the photoresist pattern as a mask until the hard mask film 62 is exposed. Thereafter, the photoresist pattern is removed by means of oxygen plasma aching and organic peeling.

### (Step 10)

The hard mask film 62, the second upper electrode layer 61b, the first upper electrode layer 61a, the first ion conductive layer 58a, and the second ion conductive layer 58b are etched successively by dry etching using the hard mask film 63 as a mask. In this regard, although the hard mask film 63 should preferably be removed completely during etching, it may remain as it is.

For example, in a case in which the second upper electrode layer 61b is formed with titanium nitride, RIE (Reactive Ion Etching) using a Cl₂ gas as a reaction gas may be performed for the successive dry etching. Meanwhile, for example, in a case in which the first upper electrode layer 61a is formed with a ruthenium alloy containing titanium, etching may be conducted by RIE using a mixture gas of a Cl₂ gas and an O₂ gas as a reaction gas.

Further, in the case of etching of the first ion conductive layer 58a, and the second ion conductive layer 58b, dry etching should preferably be stopped on the surface of the barrier insulation film 57 located below the two.

In a case in which the first ion conductive layer 58a is a SiOCH polymer film containing silicon, oxygen, carbon, and hydrogen, and the barrier insulation film 57 is a silicon nitride film or a silicon carbonitride film, etching by RIE may be conducted. The etching by RIE may be conducted using CF₄ gas, a mixture gas of a CF₄ gas and a Cl₂ gas, or a mixture gas of a CF₄ gas, a Cl₂ gas and an Ar gas, and regulating etching conditions. Using such a hard mask RIE method, films constituting the two-terminal switch 72 can be etched without exposure to oxygen plasma ashing for resist removal. In this regard, the films constituting the two-terminal switch 72 mean the second upper electrode layer 61b, the first upper electrode layer 61a, the first ion conductive layer 58a, and the second ion conductive layer 58b. Further, in a case in which an oxidation treatment with oxygen plasma is conducted after the processing, an oxidation plasma treatment can be carried out irrespective of resist peeling time.

### (Step 11)

The protection insulation film 64 is formed so as to cover the hard mask film 62, the second upper electrode layer 61b, the first upper electrode layer 61a, the first ion conductive layer 58a, the second ion conductive layer 58b, and the barrier insulation film 57 as shown in FIG. 8D. In this case, the protection insulation film 64 is, for example, a silicon nitride film, or a silicon carbonitride film with a film thickness of 30 nm. Although the protection insulation film 64 can be formed by a plasma-enhanced CVD method, it is required to be kept in a reaction chamber under reduced pressure prior to film formation, during which a problem may develop that oxygen is released from a side face of the first ion conductive layer 58a and a leak current of the first ion conductive layer 58a is increased.

In order to suppress the increase of a leak current, the deposition temperature for the protection insulation film 64 is preferably 250° C. or less. Further, with respect to the deposition of the protection insulation film 64, since a substrate is exposed to a deposition gas under reduced pressure prior to deposition, a reducing gas should not be preferably used as a source gas. For example, a silicon nitride film formed by depositing a mixture gas of SiH₄/N₂ by high density plasma at a substrate temperature of 200° C. is preferably used as the protection insulation film 64.

### (Step 12)

The interlayer insulation film 65 (for example, a silicon oxide film), the etching stopper film 66 (for example, a silicon nitride film), and the interlayer insulation film 67 (for example, a silicon oxide film) are deposited on the protection insulation film 64 in the mentioned order. Thereafter, a wiring trench, where the second wiring 68 is to be formed, and a contact hole, where the plug 69 is to be formed, are formed. Further, the barrier metal film 70 (for example, a laminate of a tantalum nitride film and a tantalum film), the second wiring 68 (for example, copper), and the plug 69 (for example, copper) are formed in the wiring trench and the contact hole using a copper dual damascene wiring process. Then, the barrier insulation film 71 (for example, a silicon nitride film) is deposited so as to cover the second wiring 68, and the interlayer insulation film 67. For forming the second wiring 68, the same process as used for forming the wiring positioned in a lower layer thereof (for example, the first wiring 55) may be used. In this case, the contact resistance between the plug 69 and the second upper electrode layer 61b can be decreased to improve the device performance, by forming the barrier metal film 70 and the second upper electrode layer 61b with the same material. The interlayer insulation film 65 and the interlayer insulation film 67 can be formed by a plasma-enhanced CVD method. For eliminating a level difference generated due to the two-terminal switch 72, an interlayer insulation film 65 may be deposited thick, and the interlayer insulation film 65 may be ground deep by CMP for planarization, thereby completing the interlayer insulation film 65 with a desired film thickness.

According to the above steps, formation of the two-terminal switch 72 and the wiring connected thereto (the plug 69, and the second wiring 68) is completed.

### Second Exemplary Embodiment

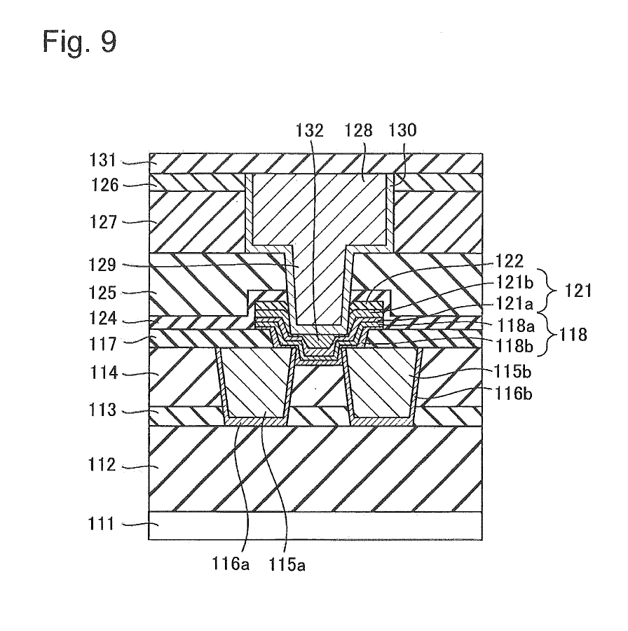

FIG. 9 is a cross-sectional view showing the configuration of a semiconductor device integrating a switching element according to the second exemplary embodiment inside a multilayer wiring layer. According to the second exemplary embodiment, a switching element is configured as a three-terminal switch. The three-terminal switch is denoted with reference sign 132 in FIG. 9.

According to the second exemplary embodiment, a multilayer wiring layer is provided with a pair of first wirings 115a and 115b, and a plug 129, and a three-terminal switch 132 is configured to have an upper electrode 121 and a variable resistance layer 118. The upper electrode 121 is provided with a first upper electrode layer 121a, and a second upper electrode layer 121b. The first wirings 115a and 115b in the multilayer wiring layer function also as a lower electrode of the three-terminal switch 132. In other words, the variable resistance layer 118 is inserted between the upper electrode 121 and the first wiring 115a or 115b. The variable resistance layer 118 is provided with a first ion conductive layer 118a and a second ion conductive layer 118b, and the variable resistance layer 118 is connected with the pair of first wirings 115a and 115b through an opening. The opening is formed in such a way to reach between the first wirings 115a and 115b of an interlayer insulation film 114.

A formation method of the multilayer wiring structure in FIG. 9 is the same as the formation method of the multilayer wiring structure according to the first exemplary embodiment (refer to FIG. 5). The multilayer wiring layer has an insulation laminate with layers stacked one on another above a semiconductor substrate 111. The insulation laminate is provided with an interlayer insulation film 112, a barrier insulation film 113, the interlayer insulation film 114, a barrier insulation film 117, a protection insulation film 124, an interlayer insulation film 125, an etching stopper film 126, an interlayer insulation film 127, and a barrier insulation film 131.

A pair of wiring trenches are formed in the interlayer insulation film 114, and the barrier insulation film 113 in the multilayer wiring layer. The side faces and the bottom faces of the wiring trenches are respectively coated with barrier metal films 116a and 116b, and additionally a pair of first wirings 115a and 115b are formed to fill the pair of wiring trenches.

A contact hole is formed through the interlayer insulation film 125, the protection insulation film 124, and the hard mask film 122, and further a wiring trench is formed through the interlayer insulation film 127, and etching stopper film 126. The side faces and the bottom faces of the contact hole and the wiring trench are coated with a barrier metal film 130. The plug 129 is formed to fill the contact hole, and a second wiring 128 is formed in such a way as to fill the wiring trench. The second wiring 128 and the plug 129 are integrated.

In the barrier insulation film 117, an opening communicating with first wirings 115a and 115b is formed. The second ion conductive layer 118b, the first ion conductive layer 118a, the first upper electrode layer 121a, and the second upper electrode layer 121b are layered one on another. They are layered one on another so as to cover a part of the first wirings 115a and 115b located inside the opening, the side face of the opening of the barrier insulation film 117, and a part of the upper surface of the barrier insulation film 117.

The three-terminal switch 132 is configured in such a way as to have the pair of first wirings 115a and 115b to be used as a lower electrode, the upper electrode 121 provided with the first upper electrode layer 121a, and the second upper electrode layer 121b, and the variable resistance layer 118. In this regard, the variable resistance layer 118 is provided with the first ion conductive layer 118a, and the second ion conductive layer 118b. More precisely, the second ion conductive layer 118b and the first wirings 115a and 115b are directly contacted inside the opening formed in the barrier insulation film 117, and the second upper electrode layer 121b is electrically connected with the plug 129 through the barrier metal film 130. Further, a hard mask film 122 is formed on the second upper electrode layer 121b. Further, the upper face and the side faces of a laminate constituted with the second ion conductive layer 118b, the first ion conductive layer 118a, the first upper electrode layer 121a, the second upper electrode layer 121b, and the hard mask film 122 are covered with the protection insulation film 124.

The thus configured three-terminal switch 132 is switched into an on-state or an off-state by applying a voltage or a current. Switching of the three-terminal switch 132 is conducted, for example, utilizing electric-field diffusion of a metal ion supplied from a metal forming the first wirings 115a and 115b to second ion conductive layer 118b and the first ion conductive layer 118a. The second upper electrode layer 121b and the barrier metal film 130 are preferably composed of the same material. Thus, the barrier metal film 130 of the plug 129 and the second upper electrode layer 121b of the three-terminal switch 132 are integrated to reduce the contact resistance, and improvement of the reliability owing to improvement of the adherence can be achieved.

When the first wirings 115a and 115b function also as a lower electrode of the three-terminal switch 132, the electrode resistance can be lowered, while the process step number is reduced. More specifically, the three-terminal switch 132 can be installed only by forming at least two photoresist mask sets as additional steps to an ordinary damascene copper wiring process. By this, reduction of the resistance and reduction of the cost of a switching element can be achieved simultaneously.

The semiconductor substrate 111 is a substrate with a semiconductor device formed. As the semiconductor substrate 111, for example, a silicon substrate, a single crystal substrate, a SOI (Silicon on Insulator) substrate, a TFT (Thin Film Transistor) substrate, and a substrate for producing a liquid crystal may be used.

The interlayer insulation film 112 is an insulation film formed on the semiconductor substrate 111. As the interlayer insulation film 112, for example, a silicon oxide film, and a low-dielectric constant film with a lower relative dielectric constant than a silicon oxide film (for example, a SiOCH film) may be used. The interlayer insulation film 112 may be a laminate of a plurality of insulation films.

The barrier insulation film 113 is a barrier insulation film placed between the interlayer insulation films 112 and 114. The barrier insulation film 113 functions as an etching-stop layer, when wiring trenches for embedding the first wirings 115a and 115b are formed. As the barrier insulation film 113, for example, a silicon nitride film, and a silicon carbonitride film can be used. The barrier insulation film 113 may be also eliminated depending on a selected etching condition of the wiring trench.

The interlayer insulation film 114 is an insulation film formed on the barrier insulation film 113. As the interlayer insulation film 114, for example, a silicon oxide film, a low-dielectric constant film with a lower relative dielectric constant than a silicon oxide film (for example, a SiOCH film) may be used. The interlayer insulation film 114 may be a laminate of a plurality of insulation films.

The first wirings 115a and 115b are wiring embedded in the wiring trenches formed in the interlayer insulation film 114, and the barrier insulation film 113. In this regard, the first wirings 115a and 115b function also as a lower electrode of the three-terminal switch 132, and are in direct contact with the second ion conductive layer 118b of the variable resistance layer 118. An electro-conductive layer such as an electrode layer may be inserted between the first wirings 115a and 115b and the variable resistance layer 118. When an electrode layer is formed, the electrode layer and the variable resistance layer 118 are deposited in a continuous step, and processed in a continuous step. The under surface of the variable resistance layer 118 is not connected with a lower layer wiring through a contact plug. As a metal composing the first wirings 115a and 115b, a metal to generate a metal ion, which is diffusible and conductive as an ion in the variable resistance layer 118, is used, and, for example, copper may be used. The first wirings 115a and 115b may be formed with an alloy containing a metal to generate a metal ion, which is diffusible and conductive as an ion in the variable resistance layer 118 (for example, copper), and aluminum.

The barrier metal films 116a and 116b are electrically conductive films having a barrier property and covers the side faces and the bottom faces of the first wirings 115a and 115b to prevent a metal forming the first wirings 115a and 115b (for example, copper) from diffusing to the interlayer insulation film 114 or an underlying layer. When the first wirings 115a and 115b are made of metals containing copper as a main component, the barrier metal films 116a and 116b may be constituted as follows. That is, as the barrier metal films 116a and 116b, a thin film of a refractory metal, or a nitride of a refractory metal, such as tantalum, tantalum nitride, titanium nitride, and tungsten carbonitride, or a laminated film thereof may be used.

The barrier insulation film 117 is formed such that the interlayer insulation film 114 and the first wirings 115a and 115b are covered. The barrier insulation film 117 has a function to prevent oxidation of a metal composing the first wirings 115a and 115b (for example, copper), or to prevent diffusion of a metal composing the first wirings 115a and 115b into the interlayer insulation film 125. Further, the barrier insulation film 117 has a function of an etching-stop layer in processing the upper electrode 121 and the variable resistance layer 118. As the barrier insulation film 117, for example, a SiC film, a silicon carbonitride film, a silicon nitride film, and a layered structure thereof may be used. The barrier insulation film 117 is preferably made of the same material as the protection insulation film 124, and the hard mask film 122.

As described above, the barrier insulation film 117 has an opening communicating with the first wirings 115a and 115b, and the first wirings 115a and 115b are in contact with the variable resistance layer 118 inside the opening. In this way, the three-terminal switch 132 can be formed on the surfaces of the first wirings 115a and 115b with small ruggedness. The side face of the opening of the barrier insulation film 117 is a tapered surface whose diameter increases as the distance from the first wirings 115a and 115b increases. The tapered surface of the opening of the barrier insulation film 117 is set to make 85° or less with respect to the upper surface of the first wirings 115a and 115b. In this way, electric field concentration at the circumference of the connection part of the first wirings 115a and 115b with the variable resistance layer 118 (near the circumference of the opening of the barrier insulation film 117) is relaxed and the insulation tolerance can be improved.

The first ion conductive layer 118a, and the second ion conductive layer 118b constitute the variable resistance layer 118, the resistance of which is changed by an action (diffusion, ion conduction, etc.) of a metal ion generated from a metal composing the first wirings 115a and 115b (lower electrode).

The first ion conductive layer 118a is constituted with a film containing silicon, oxygen, and carbon as main components, for example, a SiOCH polymer containing silicon, oxygen, carbon, and hydrogen (for example, a polymer of an organic silica compound, such as a cyclic siloxane). The SiOCH polymer film to be used as the first ion conductive layer 118a may be deposited by a plasma-enhanced CVD (Chemical Vapor Deposition) method.

The second ion conductive layer 118b has a function to prevent a metal (for example, copper) for forming the first wirings 115a and 115b from diffusing into the first ion conductive layer 118a by heating or plasma during deposition of the first ion conductive layer 118a. Further, the second ion conductive layer 118b has a function to prevent promotion of diffusion by oxidation of the first wirings 115a and 115b to be used as a lower electrode. As a metal for the second ion conductive layer 118b, for example, titanium, aluminum, zirconium, hafnium, and tantalum may be used. The metals for the second ion conductive layer 118b are oxidized during deposition of the first ion conductive layer 118a to thin films of titanium oxide, aluminum oxide, zirconium oxide, hafnium oxide, and tantalum oxide, to constitute a part of the variable resistance layer 118. The optimum film thickness of the metal film to form the second ion conductive layer 118b is from 0.5 to 1 nm. When it is thinner, oxidation of the surface of the first wirings 115a and 115b occurs slightly, and when the same is thicker, it is not oxidized completely and remains as metal.

The variable resistance layer 118 is formed such that a part of the upper surface of the first wirings 115a and 115b, the tapered surface of the opening of the barrier insulation film 117, and a part of the upper surface of the barrier insulation film 117 are covered. With respect to the variable resistance layer 118, the circumference of the connection part of the first wiring 55 with the variable resistance layer 118 is placed at least along the tapered surface of the opening portion of the barrier insulation film 117.

A metal film to be used for forming the second ion conductive layer 118b may be formed as a laminated film, or formed as a monolayer film. A metal composing the second ion conductive layer 118b (a second metal) preferably contains the same metal as a metal contained in the first upper electrode layer 121a, and the second upper electrode layer 121b (a first metal) described below. In this way, when a second metal composing the second ion conductive layer 118b diffuses into the first upper electrode layer 121a, and the second upper electrode layer 121b, generation of a defect in the first upper electrode layer 121a, and the second upper electrode layer 121b can be prevented. If a defect is generated in the first upper electrode layer 121a, or the second upper electrode layer 121b, decrease in dielectric breakdown voltage of the first ion conductive layer 118a originated from the defect may occur.

The first upper electrode layer 121a is a lower electrode layer of the upper electrode 121 and is in direct contact with the first ion conductive layer 118a. The first upper electrode layer 121a is preferably an alloy of ruthenium and a first metal, namely a ruthenium alloy, to which a first metal is added.

As the first metal to be added to a ruthenium alloy forming the first upper electrode layer 121a, it is desirable to select a metal, whose standard Gibbs energy of formation with respect to an oxidation process (a process for forming a metal ion from a metal) is larger than ruthenium in the negative direction. With respect to titanium, tantalum, zirconium, hafnium, and aluminum, in which the standard Gibbs energy of formation with respect to an oxidation process is larger than ruthenium in the negative direction, a spontaneous chemical reaction occurs more easily compared to ruthenium, and therefore the reactivity is high. Consequently, when a ruthenium alloy composing the first upper electrode layer 121a contains a first metal as listed above, the adherence to a metal bridge formed with a metal composing the first wirings 115a and 115b is improved. That is, a first metal to be contained in a ruthenium alloy composing the first upper electrode layer 121a is preferably at least one metal selected from the group consisting of titanium, tantalum, zirconium, hafnium, and aluminum. On the other hand, when the first upper electrode layer 121a is composed only of a first metal without containing ruthenium, the reactivity becomes too high, and a transit to an off-state becomes impossible.

A transit from an on-state to an off-state proceeds by an oxidation reaction (dissolving reaction) of a metal bridge. When the standard Gibbs energy of formation with respect to an oxidation process of a metal composing the first upper electrode layer 121a is larger in the negative direction than that of a metal composing the first wirings 115a and 115b, a transit to an off-state becomes impossible. This is because an oxidation reaction of the first upper electrode layer 121a proceeds more than an oxidation reaction of a metal bridge formed with a metal composing the first wirings 115a and 115b.

Therefore, as a metal material composing the first upper electrode layer 121a, an alloy of ruthenium and the first metal with a standard Gibbs energy of formation with respect to an oxidation process smaller in the negative direction than copper is preferable. Further, if copper, which is a component of a metal bridge, gets mixed in the first upper electrode layer 121a, the effect of addition of a metal with a standard Gibbs energy large in the negative direction is weakened, and therefore a first metal to be added to a ruthenium alloy is preferably a material having a barrier property against copper and a copper ion. Examples of such a metal include tantalum, titanium, and aluminum. Meanwhile, it has been known that the larger the amount of a first metal is, the more stable an on-state becomes, and that the stability is also improved by addition of 5 atm %. Especially, when titanium is used as the first metal, it is superior in transit to an off-state and stability in an on-state. Specifically, it is preferable that the first upper electrode layer 121a is formed with a ruthenium alloy containing titanium, and the titanium content in the ruthenium alloy is regulated within a range from 20 atm % or more to 30 atm % or less. The ruthenium content in the ruthenium alloy is desirably from 60 atm % or more to 90 atm % or less.

For forming the first upper electrode layer 121a, use of a sputtering method is desirable. For forming an alloy into a film by a sputtering method, there are a method by which a target of an alloy of ruthenium and a first metal is used, and a co-sputtering method by which sputtering is conducted simultaneously with a target of ruthenium and a target of a first metal in the same chamber. Moreover, for forming an alloy into a film by a sputtering method, there is an intermixing method, by which a thin film of a first metal is formed in advance, and ruthenium is deposited thereon using a sputtering method, during which an alloy is formed by the energy of colliding atoms. By using a co-sputtering method or an intermixing method, the composition of an alloy can be modulated appropriately. When an intermixing method is applied, it is preferable to conduct a heat treatment at 400° C. or less for homogenizing the mixture condition after completing deposition of a ruthenium film.

The second upper electrode layer 121b is an upper electrode layer of the upper electrode 121 and formed on the first upper electrode layer 121a. The second upper electrode layer 121b has a function to protect the first upper electrode layer 121a. In other words, through protection of the first upper electrode layer 121a by the second upper electrode layer 121b, a damage to the first upper electrode layer 121a in a production process can be suppressed so as to keep a switching characteristic of the three-terminal switch 132.

The second upper electrode layer 121b is composed of a nitride of a first metal contained in a ruthenium alloy composing the first upper electrode layer 121a. It is also favorable that a first metal is selected from the group consisting of titanium, tantalum, zirconium, hafnium, and aluminum, as described above, also because a nitride of a first metal composing the second upper electrode layer 121b comes to have electrical conductivity. Additionally, the etching speed of a nitride of a first metal composing the second upper electrode layer 121b with respect to plasma of a fluorocarbon gas to be used for etching the interlayer insulation film 65 becomes low. This low etching speed is also preferable in that the second upper electrode layer 61b is allowed to function as an etching-stop film.

When a metal other than a nitride is used for the second upper electrode layer 61b, a part of the metal diffuses into the first upper electrode layer 121a due to heating or plasma damage in a process. By the diffusion of the metal into the first upper electrode layer 121a, defects may appear in the first upper electrode layer 121a and the dielectric breakdown voltage of an ion conductive layer may possibly decrease originating from such defects.

When a metal nitride, which is stable and a compound having favorable electrical conductivity, is used in the second upper electrode layer 121b, diffusion of the metal into the first upper electrode layer 121a can be prevented. Especially, when a metal of a nitride composing the second upper electrode layer 121b and a first metal contained in a ruthenium alloy composing the first upper electrode layer 121a are identical, it is preferable in that occurrence of a defect due to diffusion of the first metal contained in a ruthenium alloy can be prevented more efficiently.

When the first upper electrode layer 121a is formed, for example, with a ruthenium alloy containing titanium, the second upper electrode layer 121b is preferably formed with titanium nitride. Further, when the first upper electrode layer 121a is formed with a ruthenium alloy containing tantalum, the second upper electrode layer 121b is preferably formed with tantalum nitride. When the metal components composing the first upper electrode layer 121a and the second upper electrode layer 121b are selected to be the same, even if a metal of the second upper electrode layer 121b diffuses into the first upper electrode layer 121a, a defect is hardly formed.

In this case, the content of a first metal contained in a nitride composing the second upper electrode layer 121b is selected larger than the content of a first metal contained in a ruthenium alloy composing the first upper electrode layer 121a. By this means, diffusion of a metal composing the first upper electrode layer 121a into a nitride composing the second upper electrode layer 121b to change the composition of a ruthenium alloy composing the first upper electrode layer 121a can be prevented.

Specifically, when the second upper electrode layer 121b is formed with titanium nitride, the content of titanium in the second upper electrode layer 121b may be from 40 atm % or more to 80 atm % or less, and especially the composition of from 40 atm % or more to 50 atm % or less is preferable. In case of 40 atm % or less, there is a risk that titanium in the first upper electrode layer 121a may diffuse into the second upper electrode layer 121b. Further, in case of 50 atm % or more, not only TiN, which is a composition of a stable titanium nitride to be used for a metal electrode, but also a crystal phase attributable to Ti₂N are detectable by an X-ray diffraction analysis.

Since presence of Ti₂N promotes oxidation, it is possible that the second upper electrode 121b is oxidized, for example, during formation of a hard mask film 122. If the second upper electrode 121b is oxidized, the specific resistance of the second upper electrode 121b increases, so that the parasitic resistance of the three-terminal switch 132 increases also.

For forming the second upper electrode layer 121b, use of a sputtering method is desirable. For forming a film of a metal nitride using a sputtering method, use of a reactive sputtering method, by which a metal target is evaporated using plasma of a mixture gas of nitrogen and argon, is preferable. A metal evaporated from a metal target reacts with nitrogen to form a metal nitride to be deposited on a substrate.

The hard mask film 122 is used as a mask for etching the second upper electrode layer 121b, the first upper electrode layer 121a, the first ion conductive layer 118a, and the second ion conductive layer 118b. As the hard mask film 122, for example, a silicon nitride film, or a silicon carbonitride film can be used. The material for the hard mask film 122 is preferably identical with that for the protection insulation film 124, and the barrier insulation film 117. In this way, the surroundings of the three-terminal switch 132 are occupied entirely with components made of an identical material so that material interfaces are integrated and entry of moisture, etc. from the outside can be prevented, and detachment of the material from the three-terminal switch 132 itself can be prevented.

The protection insulation film 124 is an insulation film having functions to prevent infliction of a damage on the three-terminal switch 132, and to prevent elimination of oxygen from the first ion conductive layer 118a. As the protection insulation film 124, for example, a silicon nitride film, and a silicon carbonitride film can be used. The protection insulation film 124 uses preferably the same material as the hard mask film 122 and the barrier insulation film 117. In the case of the same material, the protection insulation film 124 is integrated with the barrier insulation film 117 and the hard mask film 122, so that the adherence between interfaces is improved, and the three-terminal switch 132 can be better protected.

The interlayer insulation film 125 is an insulation film formed on the protection insulation film 124. As the interlayer insulation film 125, for example, a silicon oxide film, a SiOC film, and a low-dielectric constant film with a relative dielectric constant lower than a silicon oxide film (for example, a SiOCH film) can be used. The interlayer insulation film 125 may be a laminate of a plurality of insulation films. The interlayer insulation film 125 may use the same material as the interlayer insulation film 127. In the interlayer insulation film 125, a contact hole for filling a plug 129 is formed. The contact hole is coated with the barrier metal film 130, and the plug 129 is formed on the barrier metal film 130 so as to fill the contact hole.

The etching stopper film 126 is an insulation film provided between the interlayer insulation films 125 and 127. The etching stopper film 126 functions as an etching-stop layer, when a wiring trench for embedding the second wiring 128 is processed. As the etching stopper film 126, for example, a silicon nitride film, a SiC film, and a silicon carbonitride film may be used.

The interlayer insulation film 127 is an insulation film formed on the etching stopper film 126. As the interlayer insulation film 127, for example, a silicon oxide film, a SiOC film, and a low-dielectric constant film with a relative dielectric constant lower than a silicon oxide film (for example, a SiOCH film) can be used. The interlayer insulation film 127 may be a laminate of a plurality of insulation films. The interlayer insulation film 127 may use the same material as the interlayer insulation film 125.

A wiring trench for embedding the second wiring 128 is formed in the etching stopper film 126 and the interlayer insulation film 127. The side faces and the bottom face of the wiring trench are coated with the barrier metal film 130, and the second wiring 128 is formed on the barrier metal film 130 so as to fill the wiring trench. The etching stopper film 126 may be even eliminated depending on a selected etching condition of the wiring trench.

The second wiring 128 is wiring embedded in a wiring trench formed in the interlayer insulation film 127 and the etching stopper film 126. The second wiring 128 is integrated with the plug 129. The plug 129 is embedded in a contact hole formed through the interlayer insulation film 125, the protection insulation film 124, and the hard mask film 122. The plug 129 is electrically connected with the second upper electrode layer 121b through the barrier metal film 130. For example, copper may be used for the second wiring 128 and the plug 129.

The diameter or the area of a region where the plug 129 (to be precise, the barrier metal film 130) is in contact with the second upper electrode layer 121b is selected in such a way as to be smaller than the diameter or the area of a region where the first wirings 115a and 115b are in contact with the variable resistance layer 118. By such a selection, generation of a void in filling plating into a contact hole can be suppressed.

The barrier metal film 130 covers the side faces and the bottom faces of the second wiring 128, and the plug 129. The barrier metal film 130 is an electrically conductive film having a barrier property and prevents a metal (for example, copper) forming the second wiring 128 (including plug 129) from diffusing to the interlayer insulation films 125 and 127 or an underlying layer. When the second wiring 128 and the plug 129 are made of metal elements including copper as a main component, a refractory metal, a nitride of a refractory metal, or a laminated film thereof may be used as the barrier metal film 130. As such a refractory metal, a nitride of a refractory metal, or a laminated film thereof, a refractory metal, or a nitride of a refractory metal, such as tantalum, tantalum nitride, titanium nitride, and tungsten carbonitride, or a laminated film thereof are conceivable.

A part of the barrier metal film 130, which contacts at least the second upper electrode layer 121b, is preferably made of the same material as the second upper electrode layer 121b. When, for example, the barrier metal film 130 is constituted with a laminate of a lower layer formed with tantalum nitride and an upper layer formed with tantalum, tantalum nitride, which is the material for the lower layer, is preferably used for the second upper electrode layer 121b.

The barrier insulation film 131 is formed so as to cover the second wiring 128 and the interlayer insulation film 127, and is an insulation film having functions of preventing a metal (for example, copper) to form the second wiring 128 from oxidation, and preventing the metal to form the second wiring 128 from diffusing to an upper layer. As the barrier insulation film 131, for example, a silicon carbonitride film, a silicon nitride film, and a laminate thereof may be used.

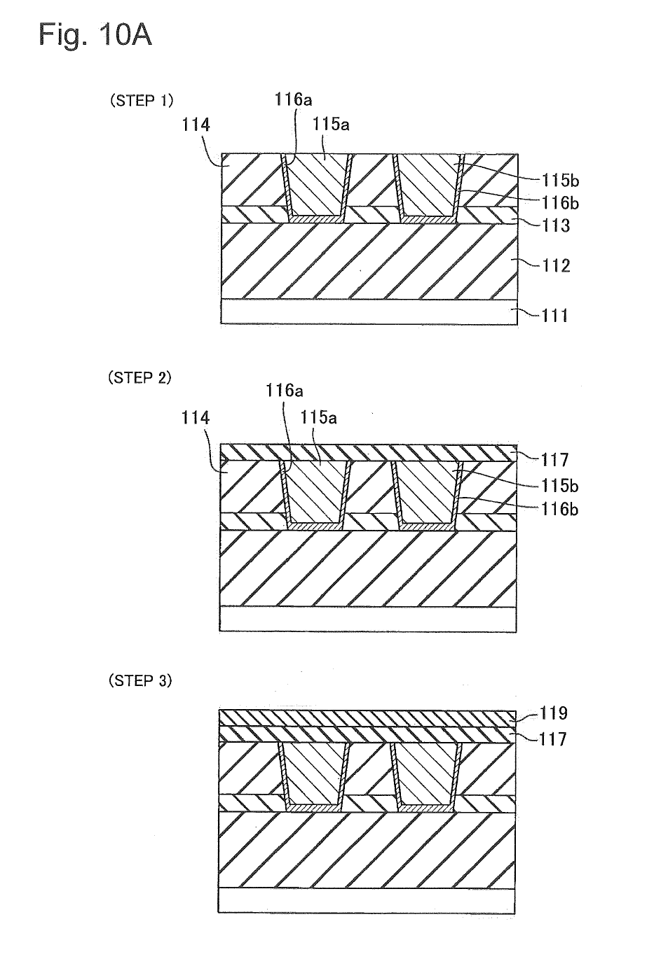

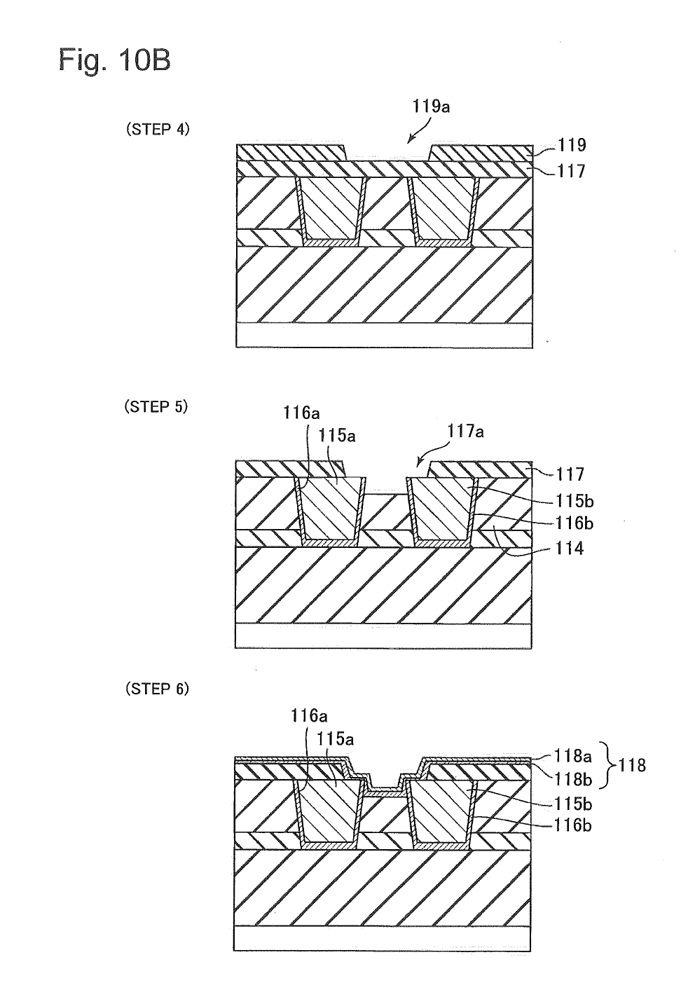

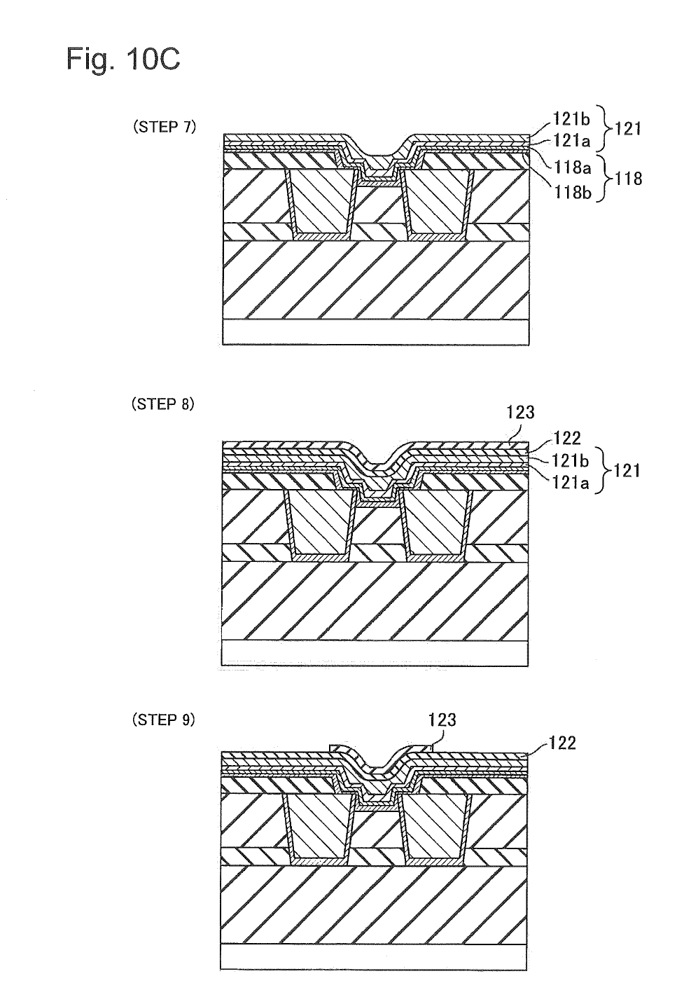

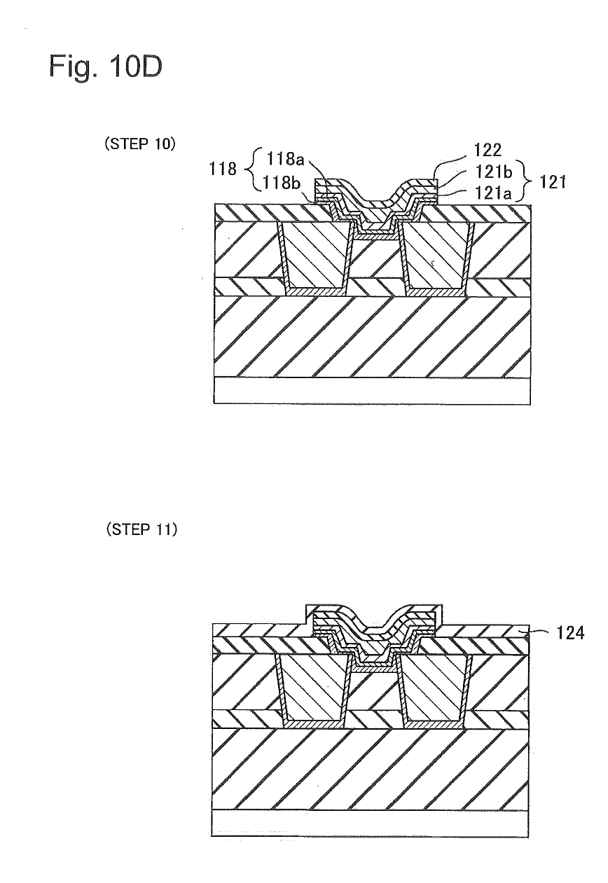

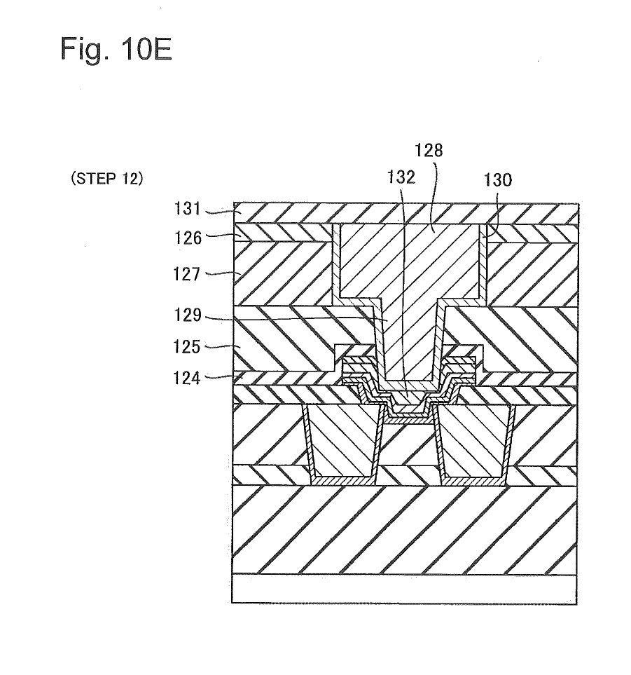

FIG. 10A to FIG. 10E are cross-sectional views schematically showing an example of a method for producing a semiconductor device integrating a switching element according to the second exemplary embodiment in a multilayer wiring layer as illustrated in FIG. 9.

### (Step 1)

As shown in FIG. 10A, firstly the interlayer insulation film 112 (for example, a silicon oxide film with a film thickness of 300 nm) is deposited on the semiconductor substrate 111 (for example, a substrate with a semiconductor device formed). Further the barrier insulation film 113 (for example, a silicon nitride film with a film thickness of 30 nm) is deposited on the interlayer insulation film 112.

Thereafter, the interlayer insulation film 114 (for example, a silicon oxide film with a film thickness of 200 nm) is deposited on the barrier insulation film 113. Then, wiring trenches corresponding to the first wirings 115a and 115b are formed using a lithography method (including formation of a photoresist, dry etching, and removal of the photoresist) in the interlayer insulation film 114, and the barrier insulation film 113. Then, the wiring trenches are coated with the barrier metal films 116a and 116b, and the first wirings 115a and 115b (for example, copper wiring) are formed on the barrier metal films 116a and 116b so as to fill the wiring trenches. In this case, as the barrier metal films 116a and 116b, for example, a laminate of a tantalum nitride film with a film thickness of 5 nm and a tantalum film with a film thickness of 5 nm is used. In this Step 1, the interlayer insulation films 112 and 114 may be formed by a plasma-enhanced CVD method.

In Step 1, the first wirings 115a and 115b may be formed by a series of formation procedures as follows. For example, the barrier metal films 116a and 116b are formed by a PVD method, further a copper seed is formed by a PVD method, and then a copper film is formed by an electrolytic plating method so as to fill the wiring trenches. Then, after a heat treatment at a temperature of 200° C. or more, a surplus copper film other than within the wiring trench is removed by a CMP method. The first wirings 115a and 115b can be formed as above. For such a series of copper wiring formation procedures, a technique common in the art may be applied. By grinding surplus copper, an embedded wiring (damascene wiring) embedded in the trench is formed, and by polishing the interlayer insulation film 114, planarization can be carried out.

### (Step 2)

Next, the barrier insulation film 117 (for example, a silicon carbonitride film with a film thickness of 30 nm) is formed so as to cover the first wirings 115a and 115b and the interlayer insulation film 114. In this regard, the barrier insulation film 117 may be formed by a plasma-enhanced CVD method. The film thickness of the barrier insulation film 117 is preferably approximately from 10 nm to 50 nm.

### (Step 3)

Next, the hard mask film 119 (for example, a silicon oxide film) is formed on the barrier insulation film 117. In this case, the hard mask film 119 preferably uses a material different from that for the barrier insulation film 117 from a viewpoint of keeping the etching selection ratio in a dry etching process high, and it may be an insulation film or an electro-conductive film. As the hard mask film 119, for example, a silicon oxide film, a silicon nitride film, TiN, Ti, tantalum, tantalum nitride may be used. Further as the hard mask film 119, a laminate of a silicon nitride film and a silicon oxide film may be used.

### (Step 4)

A photoresist pattern (not illustrated) with an opening is formed above the hard mask film 119. The opening 119a is formed in the hard mask film 119 as shown in FIG. 10B by performing dry etching using the photoresist pattern as a mask. Thereafter the photoresist pattern is eliminated by oxygen plasma ashing, etc. In this case dry etching is not always required to stop at the upper surface of the barrier insulation film 117 but a part of the barrier insulation film 117 may be etched.

### (Step 5)

Next, the opening 117a is formed in the barrier insulation film 117 by etching-back (dry etching) the barrier insulation film 117 exposed through the opening 119a of the hard mask film 119 using the hard mask film 119 as a mask. In the opening 117a of the barrier insulation film 117, a part of the first wirings 115a and 115b is exposed. In this case, a part of the interlayer insulation film 114, as is inside the opening 117a of the barrier insulation film 117, may be etched partially. Step 5 of FIG. 10B shows a situation where a part of the interlayer insulation film 114 inside the opening 117a of the barrier insulation film 117 is partially etched. Then, by conducting an organic peeling treatment with an amine type pealing liquid, etc., copper oxide formed on the exposed surface of the first wirings 115a and 115b is removed, and an etching product generated during etch-back is removed. Although the hard mask film 119 is preferably removed completely during etch-back in Step 5, if the same is an insulating material, it may remain as it is. In this regard, the shape of the opening 117a of the barrier insulation film 117 may be circular, square, or rectangular, and the diameter of the circle, or the side length of the square or the rectangle may be from 20 nm to 500 nm. Further, in Step 5, at etch-back of the barrier insulation film 117, the side faces of the opening 117a of the barrier insulation film 117 can be formed to tapered surfaces by applying reactive dry etching. For reactive dry etching, a gas containing fluorocarbon may be used as an etching gas.

### (Step 6)

The variable resistance layer 118 provided with the first ion conductive layer 118a and the second ion conductive layer 118b is formed. More precisely, a titanium film with a film thickness of 0.5 nm and an aluminum film with a film thickness of 0.5 nm are deposited in the mentioned order forming a metal film with a total film thickness of 1 nm, so as to cover the first wirings 115a and 115b and the barrier insulation film 117. The titanium film and the aluminum film can be formed by a PVD method or a CVD method.

A SiOCH polymer film with a film thickness of 6 nm is formed by a plasma-enhanced CVD as the first ion conductive layer 118a. According to the present exemplary embodiment, a SiOCH polymer film to be used as the first ion conductive layer 118a is formed as follows. A source material for a cyclic organic siloxane, and helium as a carrier gas are supplied in a reaction chamber, and when the supply of the both is stabilized such that the reaction chamber pressure becomes constant, application of RF power is initiated. The supply rate of the source material is from 10 to 200 sccm, and with respect to helium, 500 sccm of helium is supplied through a source material vaporizer, and 500 sccm of helium is supplied directly into a reaction chamber through a separate line

A titanium film and an aluminum film are auto-oxidized by exposure to a source material for a SiOCH polymer film containing oxygen during formation of the first ion conductive layer 118a. The second ion conductive layer 118b constituting a part of the variable resistance layer 118 is formed by oxidation of the titanium film and the aluminum film.

Since moisture, etc. sticks to the opening 117a of the barrier insulation film 117 by an organic peeling treatment in Step 5, degassing is preferably conducted in Step 6 by a Heat Treatment at a Temperature of approximately from 250° C. to 350° C. under reduced pressure prior to formation of the variable resistance layer 118. In this case, degassing is preferably conducted under vacuum or under a nitrogen atmosphere, so as not to oxidize again a surface of the first wirings 115a and 115b formed with copper. Further, in Step 6, the first wirings 115a and 115b exposed out of the opening of the barrier insulation film 117 may be subjected to a gas cleaning treatment using a H₂ gas or a plasma cleaning treatment prior to formation of the variable resistance layer 118. In this way, during formation of the variable resistance layer 118, oxidation of copper of the first wirings 115a and 115b can be suppressed, and thermal diffusion (mass transfer) of copper in the process can be suppressed.

### (Step 7)

As shown in FIG. 10C, a thin film of a ruthenium alloy containing titanium with a film thickness of 10 nm is formed on the variable resistance layer 118 by a co-sputtering method as the first upper electrode layer 121a. In this case, a ruthenium target and a titanium target are present in the same chamber, and a ruthenium alloy film is deposited by sputtering at the same time. The content of ruthenium in the ruthenium alloy containing titanium can be controlled to a desired value by regulating the application power to the ruthenium target and the application power to the titanium target. In an inventors' experimental system, the ruthenium content in the “ruthenium alloy containing titanium” could be controlled to 75 atm %, and the titanium content to 25 atm % by regulating the application power to the ruthenium target at 150 W, and the application power to the titanium target at 50 W.

Further, the second upper electrode layer 121b is formed on the first upper electrode layer 121a. The first upper electrode layer 121a and the second upper electrode layer 121b constitute the upper electrode 121. As the second upper electrode layer 121b, for example, a titanium nitride film with a film thickness of 25 nm is formed by a reactive sputtering method. In forming a titanium nitride film by a reactive sputtering method, a nitrogen gas and an argon gas are introduced in a chamber. In this case, by regulating the application power to a titanium target, and the ratio of the nitrogen gas to the argon gas supplied to the chamber, the titanium content in the titanium nitride film can be adjusted. In an inventor's experimental system, the titanium content in the titanium nitride film could be adjusted to 50 atm % by setting the application power to a titanium target at 600 W, and the ratio of the flow rate of the nitrogen gas to the flow rate of the argon gas at 2:1.

### (Step 8)

The hard mask film 122 (for example, a silicon nitride film or a silicon carbonitride film with a film thickness of 30 nm), and the hard mask film 123 (for example, a silicon oxide film with a film thickness of 90 nm) are layered in the mentioned order. The hard mask films 122 and 123 may be formed using a plasma-enhanced CVD method. The hard mask films 122 and 123 may be formed using a plasma-enhanced CVD method common in the technical field. The hard mask films 122 and 123 are preferably films formed with different materials, and, for example, the hard mask film 122 may be formed with a silicon nitride film, and the hard mask film 123 may be formed with a silicon oxide film. In this case the hard mask film 122 is preferably made of the same material as for the protection insulation film 124 described below and the barrier insulation film 117. That is, by placing the same material to surround entirely a switching element, interfaces of components surrounding the switching element are integrated, so that entry of moisture, etc. from the outside can be prevented, and detachment of a material from the switching element can be prevented.

Although the hard mask film 122 can be formed by a plasma-enhanced CVD method, the inside of a reaction chamber is required to be maintained under reduced pressure before deposition. There can be a risk of a trouble that oxygen is eliminated from the first ion conductive layer 118a during maintenance under reduced pressure, and a leak current from the first ion conductive layer 118a increases due to an oxygen defect.

For suppression of the increase in a leak current, the film deposition temperature should be preferably 350° C. or lower, more preferably 250° C. or lower. Further, since exposure to a deposition gas under reduced pressure occurs before the film deposition, a reducing gas is preferably not used as a source gas for the hard mask film 122. For example, for the hard mask film 122, use of a high density silicon nitride film formed by using a mixture gas of SiH₄/N₂ as a source material and generating high density plasma is preferable.

### (Step 9)

Next, a photoresist pattern (not illustrated) for patterning the first ion conductive layer 58a, the second ion conductive layer 58b, the first upper electrode layer 61a, and the second upper electrode layer 61b is formed on the hard mask film 123. After the formation of the photoresist pattern, the hard mask film 123 is etched by dry etching using the photoresist pattern as a mask until the hard mask film 122 is exposed as illustrated in FIG. 10C. Thereafter, the photoresist pattern is removed by means of oxygen plasma aching and organic peeling.

### (Step 10)

The hard mask film 122, the second upper electrode layer 121b, the first ion conductive layer 118a, and the second ion conductive layer 118b are etched successively by dry etching using the hard mask film 123 as a mask as illustrated in FIG. 10D. In this regard, although the hard mask film 123 should preferably be removed completely during etch-back, it may remain as it is.

In Step 10, when, for example, the second upper electrode layer 121b is formed with titanium nitride, processing by RIE using a Cl₂ gas as a reaction gas is possible. When the first upper electrode layer 121a is formed with a ruthenium alloy containing titanium, processing by RIE using a mixture gas of a Cl₂ gas and an O₂ gas as a reaction gas is possible. In etching the first ion conductive layer 118a and the second ion conductive layer 118b, dry etching is preferably terminated on the underlying barrier insulation film 117.

When the first ion conductive layer 118a is a SiOCH polymer film containing silicon, oxygen, carbon, and hydrogen, and the barrier insulation film 117 is a silicon nitride film or a silicon carbonitride film, etching by RIE may be performed. Such etching by RIE may be performed, for example, using a CF₄ gas, a mixture gas of a CF₄ gas and a Cl₂ gas, or a mixture gas of a CF₄ gas, a Cl₂ gas and an Ar gas and modulating etching conditions. Films constituting the three-terminal switch 132 can be etched using such a hard mask RIE method without exposing an oxygen plasma ashing for removing a resist. In this regard, films constituting the three-terminal switch 132 are the second upper electrode layer 121b, the first upper electrode layer 121a, the first ion conductive layer 118a, and the second ion conductive layer 118b. Further, in a case in which an oxidation treatment with oxygen plasma is conducted after the processing, an oxidation plasma treatment can be carried out irrespective of resist peeling time.

### (Step 11)

Next, the protection insulation film 124 (for example, a silicon nitride film with a film thickness of 30 nm) is deposited so as to cover the hard mask film 122, the second upper electrode layer 121b, the first upper electrode layer 121a, the first ion conductive layer 118a, the second ion conductive layer 118b, and the barrier insulation film 117.

In Step 11, the protection insulation film 124 can be deposited by a plasma-enhanced CVD method, but, in a reaction chamber is required to be maintained under reduced pressure prior to deposition. In this case, a problem may develop that oxygen is released from a side face of the first ion conductive layer 118a and a leak current of the first ion conductive layer 118a is increased.

In order to suppress the increase of a leak current, the deposition temperature for the protection insulation film 124 is preferably 250° C. or less. Further, with respect to the deposition of the protection insulation film 124, since a substrate is exposed to a deposition gas under reduced pressure prior to deposition, a reducing gas should not be preferably used as a source gas. For example, a silicon nitride film formed of a mixture gas of SiH₄/N₂ by high density plasma at a substrate temperature of 200° C. is preferably used as the protection insulation film 124.

### (Step 12)

Next, the interlayer insulation film 125 (for example, a SiOC film), and the interlayer insulation film 127 (for example, a silicon oxide film) are deposited on the protection insulation film 124 in the mentioned order. Further, the etching stopper film 126 is formed on the interlayer insulation film 127. Thereafter, a wiring trench, where the second wiring 128 is to be formed, and a contact hole, where the plug 129 is to be formed, are formed. Further, the barrier metal film 130 (for example, a laminate of a tantalum nitride film and a tantalum film), the second wiring 128 (for example, copper), and the plug 129 (for example, copper) are formed in the wiring trench and the contact hole using a copper dual damascene wiring process. Then, the barrier insulation film 131 (for example, a silicon nitride film) is deposited so as to cover the second wiring 128, and the interlayer insulation film 127. In Step 12 for forming the second wiring 128, the same process as used for forming the wiring positioned in a lower layer thereof (for example, the first wirings 115a and 115b) may be used. In this case, the contact resistance between the plug 129 and the second upper electrode layer 121b can be decreased to improve the device performance (reduction of the resistance of a three-terminal switch 132 in an on-state), by forming the barrier metal film 130 and the second upper electrode layer 121b with the same material. Further, in Step 12, the interlayer insulation film 125 and the interlayer insulation film 127 can be formed by a plasma-enhanced CVD method. Further, in Step 12, for eliminating a level difference generated due to the three-terminal switch 132, an interlayer insulation film 125 may be deposited thick, and the interlayer insulation film 125 may be ground deep by CMP for planarization, thereby completing the interlayer insulation film 125 with a desired film thickness.

According to the above steps, formation of the three-terminal switch 132 and the wiring connected thereto (the plug 129, and the second wiring 128) is completed.

Although exemplary embodiments according to the present invention are described specifically above, the present invention be not construed as being limited to the above exemplary embodiments. It is obvious to a person skilled in the art that the present invention may be exercised with various modifications. Various modifications and alterations will be possible without departing from the spirit and scope of the invention as defined in the appended claims, which are obviously included in the scope of the present invention.

With respect to a switching element according to the first exemplary embodiment as shown in FIG. 2, etc., it is described above that the content of a first metal in a ruthenium alloy composing the first upper electrode layer 22a is made lower than the content of a first metal in a nitride composing the second upper electrode layer 22b. This is equivalent to that the content of a first metal in a nitride composing the second upper electrode layer 22b is made larger than the content of a first metal in a ruthenium alloy composing the first upper electrode layer 22a.

With respect to a semiconductor device according to the first exemplary embodiment in FIG. 5, etc., it is described above that the content of a first metal in a nitride composing the second upper electrode layer 61b is made larger than the content of a first metal in a ruthenium alloy composing the first upper electrode layer 61a. This is equivalent to that the content of a first metal in a ruthenium alloy composing the first upper electrode layer 61a is made lower than the content of a first metal in a nitride composing the second upper electrode layer 61b.

With respect to a semiconductor device according to the second exemplary embodiment in FIG. 9, etc., it is described above that the content of a first metal in a nitride composing the second upper electrode layer 121b is made larger than the content of a first metal in a ruthenium alloy composing the first upper electrode layer 121a. This is equivalent to that the content of a first metal in a ruthenium alloy composing the first upper electrode layer 121a is made lower than the content of a first metal in a nitride composing the second upper electrode layer 121b.

A part or all of the above exemplary embodiments may be expressed as in the following Supplementary notes without limitation thereto.

(Supplementary note 1) A switching element provided with a first electrode, a second electrode, and a variable resistance layer that is disposed between the first electrode and the second electrode, and has ion conductivity; wherein:

the first electrode contains a metal that generates a metal ion conductive in the variable resistance layer,

the second electrode is provided with a first electrode layer formed in contact with the variable resistance layer and a second electrode layer formed in contact with the first electrode layer;

the first electrode layer is formed with a ruthenium alloy containing ruthenium and a first metal with a standard Gibbs energy of formation with respect to an oxidation process larger in the negative direction than ruthenium;

the second electrode layer is formed with a nitride containing the first metal, and

the content of the first metal in the first electrode layer is lower than the content of the first metal in the second electrode layer.

(Supplementary note 2) The switching element according to Supplementary note 1, wherein the first metal is at least one metal selected from the group consisting of titanium, tantalum, zirconium, hafnium, and aluminum.
(Supplementary note 3) The switching element according to Supplementary note 1 or 2, wherein the first electrode layer contains ruthenium as a main component, and the content of the first metal therein is in a range from 10 atm % or more to 40 atm % or less.
(Supplementary note 4) The switching element according to any one of Supplementary notes 1 to 3, wherein the first metal is titanium, and the content of titanium in the first electrode layer is in a range from 20 atm % or more to 30 atm % or less, and the content of titanium in the second electrode layer is in a range from 40 atm % or more to 80 atm % or less.
(Supplementary note 5) The switching element according to any one of Supplementary notes 1 to 4, wherein a metal conductive in the variable resistance layer includes copper.
(Supplementary note 6) The switching element according to any one of Supplementary notes 1 to 5, wherein the variable resistance layer is provided with a first ion conductive layer containing at least silicon, oxygen, and carbon as main components, and the relative dielectric constant of the first ion conductive layer is in a range from 2.1 or more to 3.0 or less.
(Supplementary note 7) The switching element according to Supplementary note 6 provided further with a second ion conductive layer placed between the first ion conductive layer and the first electrode; wherein

the second ion conductive layer is formed with an oxide of a second metal, and

the second metal is at least one metal selected from the group consisting of titanium, tantalum, zirconium, hafnium, and aluminum.

(Supplementary note 8) The switching element according to Supplementary note 7, wherein the first metal and the second metal are the same.
(Supplementary note 9) A semiconductor device provided with a semiconductor substrate, and a multilayer wiring layer including a copper-made wiring and a copper-made plug, formed above the semiconductor substrate, wherein

a switching element is formed in the multilayer wiring layer,

the switching element is provided with a copper-made lower electrode copper wiring to be used as a lower electrode of the switching element, an upper electrode electrically connected with the plug, and a variable resistance layer with ion-conductivity formed between the lower electrode copper wiring and the upper electrode,

the upper electrode is provided with the first upper electrode layer formed in contact with the variable resistance layer and the second upper electrode layer formed in contact with the first upper electrode layer,

the first upper electrode layer is formed with a ruthenium alloy containing ruthenium and a first metal with a standard Gibbs energy of formation with respect to an oxidation process larger in the negative direction than ruthenium;

the second upper electrode layer is formed with a nitride containing the first metal; and

the content of the first metal in the first upper electrode layer is lower than the content of the first metal in the second upper electrode layer.

(Supplementary note 10) The semiconductor device according to Supplementary note 9, wherein the first metal is at least one metal selected from the group consisting of titanium, tantalum, zirconium, hafnium, and aluminum.
(Supplementary note 11) The semiconductor device according to Supplementary note 9 or 10, wherein the first electrode layer contains ruthenium as a main component, and the content of the first metal therein is in a range from 10 atm % or more to 40 atm % or less.
(Supplementary note 12) The semiconductor device according to any one of Supplementary notes 9 to 11, wherein the first metal is titanium, and the content of titanium in the first electrode layer is in a range from 20 atm % or more to 30 atm % or less, and the content of titanium in the second electrode layer is in a range from 40 atm % or more to 80 atm % or less.
(Supplementary note 13) The semiconductor device according to any one of Supplementary notes 9 to 12, wherein a metal conductive in the variable resistance layer includes copper.
(Supplementary note 14) The semiconductor device according to any one of Supplementary notes 9 to 13, wherein the variable resistance layer is provided with a first ion conductive layer containing at least silicon, oxygen, and carbon as main components, and the relative dielectric constant of the first ion conductive layer is in a range from 2.1 or more to 3.0 or less.
(Supplementary note 15) The semiconductor device according to Supplementary note 14 provided further with a second ion conductive layer placed between the first ion conductive layer and the first electrode; wherein

the second ion conductive layer is formed with an oxide of a second metal, and

the second metal is at least one metal selected from the group consisting of titanium, tantalum, zirconium, hafnium, and aluminum.

(Supplementary note 16) The semiconductor device according to Supplementary note 15, wherein the first metal and the second metal are the same.
(Supplementary note 17) A method for producing a switching element provided with a first electrode, a second electrode, and a variable resistance layer that is placed between the first electrode and the second electrode, and has ion conductivity, including:

a step of forming the first electrode with a ruthenium alloy that generates a metal ion conductive in the variable resistance layer, and contains ruthenium and a first metal with a standard Gibbs energy of formation with respect to an oxidation process larger in the negative direction than ruthenium; and

a step of forming the second electrode to include the first electrode layer in contact with the variable resistance layer, and the second electrode layer formed with a nitride containing the first metal in contact with the first electrode layer;

wherein the content of the first metal in the first electrode layer of the the second electrode is lower than the content of the first metal in the second electrode layer of the the second electrode.

(Supplementary note 18) The method for producing a switching element according to Supplementary note 17, wherein the first electrode layer and the second electrode layer of the second electrode are layered one after another on the variable resistance layer, and then patterned using a common mask.
(Supplementary note 19) The method for producing a switching element according to Supplementary note 17, wherein the variable resistance layer, the first electrode layer of the second electrode, and the second electrode layer of the second electrode are layered one after another, and then patterned using a common mask.
(Supplementary note 20) The method for producing a switching element according to any one of Supplementary notes 17 to 19, wherein the first metal is at least one metal selected from the group consisting of titanium, tantalum, zirconium, hafnium, and aluminum.
(Supplementary note 21) The method for producing a switching element according to any one of Supplementary notes 17 to 20, wherein the first electrode layer of the second electrode contains ruthenium as a main component, and the content of the first metal therein is in a range from 10 atm % or more to 40 atm % or less.
(Supplementary note 22) The method for producing a switching element according to any one of Supplementary notes 17 to 21, wherein the first metal is titanium, and the content of titanium in the first electrode layer of the second electrode is in a range from 20 atm % or more to 30 atm % or less, and the content of titanium in the second electrode layer of the second electrode is from in a range 40 atm % or more to 80 atm % or less.
(Supplementary note 23) The method for producing a switching element according to any one of Supplementary notes 17 to 22, wherein a metal conductive in the variable resistance layer includes copper.
(Supplementary note 24) The method for producing a switching element according to any one of Supplementary notes 17 to 23, wherein the variable resistance layer is provided with a first ion conductive layer containing at least silicon, oxygen, and carbon as main components, and the relative dielectric constant of the first ion conductive layer is in a range from 2.1 or more to 3.0 or less.
(Supplementary note 25) The method for producing a switching element according to Supplementary note 24 provided further with a second ion conductive layer placed between the first ion conductive layer and the first electrode; wherein

the second ion conductive layer is formed with an oxide of a second metal, and

the second metal is at least one metal selected from the group consisting of titanium, tantalum, zirconium, hafnium, and aluminum.

(Supplementary note 26) The method for producing a switching element according to Supplementary note 24, wherein the first metal and the second metal are the same.

### INDUSTRIAL APPLICABILITY

A variable resistance element according to the present invention can be utilized as a nonvolatile switching element, and especially the present invention can be utilized favorably as a nonvolatile switching element constituting an electronic device, such as a programmable logic and a memory.

This application is based upon and claims the benefit of priority from Japanese patent application No. 2014-45013, filed on Mar. 7, 2014, the disclosure of which is incorporated herein in its entirety by reference.

### REFERENCE SIGNS LIST

21 lower electrode
21a tantalum film
21b copper film
22 upper electrode
22a first upper electrode layer
22b second upper electrode layer
23 variable resistance layer
23a first ion conductive layer
23b second ion conductive layer
24 metal bridge
25 metal ion
26 low-resistance silicon substrate
27 metallic layer
51 semiconductor substrate
52 interlayer insulation film
53 barrier insulation film
54 interlayer insulation film
55 first wiring
56 barrier metal film
57 barrier insulation film
57a opening
58 variable resistance layer
58a first ion conductive layer
58b second ion conductive layer
59 hard mask film
59a opening
61 upper electrode
61a first upper electrode layer
61b second upper electrode layer
62, 63 hard mask film
64 protection insulation film
65 interlayer insulation film
66 etching stopper film
67 interlayer insulation film
68 second wiring
69 plug
70 barrier metal film
71 barrier insulation film
72 two-terminal switch
111 semiconductor substrate
112 interlayer insulation film
113 barrier insulation film
114 interlayer insulation film
115a, 115b first wiring
116a, 116b barrier metal film
117 barrier insulation film
117a opening
118 variable resistance layer
118a first ion conductive layer
118b second ion conductive layer
119 hard mask film
119a opening
121 upper electrode
121a first upper electrode layer
121b second upper electrode layer
122, 123 hard mask film
124 protection insulation film
125 interlayer insulation film
126 etching stopper film
127 interlayer insulation film
128 second wiring
129 plug
130 barrier metal film
131 barrier insulation film
132 three-terminal switch
201 lower electrode
202 upper electrode
203 ion conductive layer
301 first switch
301a first electrode (active electrode)
301b second electrode (inactive electrode)
302 second switch
302a first electrode (active electrode)
302b second electrode (inactive electrode)
303 first node
304 second node
305 common node
401 first electrode
402 second electrode
403 ion conductive layer
404 titanium oxide film

1. A switching element comprising:
a first electrode,
a second electrode, and
a variable resistance layer with ion-conductivity disposed between the first electrode and the second electrode; wherein:
the first electrode includes a metal that generates a metal ion conductive in the variable resistance layer,
the second electrode is provided with a first electrode layer formed in contact with the variable resistance layer and a second electrode layer formed in contact with the first electrode layer;
the first electrode layer is formed with a ruthenium alloy containing ruthenium and a first metal with a standard Gibbs energy of formation with respect to an oxidation process larger in the negative direction than ruthenium;
the second electrode layer is formed with a nitride containing the first metal, and
the content of the first metal in the first electrode layer is lower than the content of the first metal in the second electrode layer.

2. The switching element according to claim 1, wherein the first metal is at least one metal selected from the group consisting of titanium, tantalum, zirconium, hafnium, and aluminum.

3. The switching element according to claim 1, wherein the first electrode layer contains ruthenium as a main component, and the content of the first metal therein is in a range from 10 atm % or more to 40 atm % or less.

4. The switching element according to claim 1, wherein
the first metal is titanium,
the content of titanium in the first electrode layer is in a range from 20 atm % or more to 30 atm % or less, and
the content of titanium in the second electrode layer is in a range from 40 atm % or more to 80 atm % or less.

5. The switching element according to claim 1, wherein
a metal conductive in the variable resistance layer includes copper.

6. The switching element according to claim 1, wherein
the variable resistance layer is provided with a first ion conductive layer containing at least silicon, oxygen, and carbon as main components, and
the relative dielectric constant of the first ion conductive layer is in a range from 2.1 or more to 3.0 or less.

7. The switching element according to claim 6, further comprising a second ion conductive layer disposed between the first ion conductive layer and the first electrode; wherein
the second ion conductive layer is formed with an oxide of a second metal, and
the second metal is at least one metal selected from the group consisting of titanium, tantalum, zirconium, hafnium, and aluminum.

8. The switching element according to claim 7, wherein
the first metal and the second metal are the same.

9. A semiconductor device provided with a semiconductor substrate, and a multilayered wiring layer comprising a copper-made wiring and a copper-made plug, formed over the semiconductor substrate, wherein
a switching element is formed in the multilayered wiring layer,
the switching element is provided with a copper-made lower electrode copper wiring to be used as a lower electrode of the switching element, an upper electrode electrically connected with the plug, and a variable resistance layer with ion-conductivity formed between the lower electrode copper wiring and the upper electrode,
the upper electrode is provided with the first upper electrode layer formed in contact with the variable resistance layer and the second upper electrode layer formed in contact with the first upper electrode layer,
the first upper electrode layer is formed with a ruthenium alloy containing ruthenium and a first metal with a standard Gibbs energy of formation with respect to an oxidation process larger in the negative direction than ruthenium;
the second upper electrode layer is formed with a nitride containing the first metal; and
the content of the first metal in the first upper electrode layer is lower than the content of the first metal in the second upper electrode layer.

10. (canceled)

11. The semiconductor device according to claim 9, wherein
the first metal is at least one metal selected from the group consisting of titanium, tantalum, zirconium, hafnium, and aluminum.

12. The semiconductor device according to claim 9, wherein
the first electrode layer contains ruthenium as a main component, and the content of the first metal therein is in a range from 10 atm % or more to 40 atm % or less.

13. The semiconductor device according to claim 9, wherein
the first metal is titanium, and the content of titanium in the first electrode layer is in a range from 20 atm % or more to 30 atm % or less, and
the content of titanium in the second electrode layer is in a range from 40 atm % or more to 80 atm % or less.

14. The semiconductor device according to claim 9, wherein
a metal conductive in the variable resistance layer includes copper.

15. The semiconductor device according to claim 9, wherein
the variable resistance layer is provided with a first ion conductive layer containing at least silicon, oxygen, and carbon as main components, and the relative dielectric constant of the first ion conductive layer is in a range from 2.1 or more to 3.0 or less.

16. The semiconductor device according to claim 15, further comprising a second ion conductive layer placed between the first ion conductive layer and the first electrode; wherein
the second ion conductive layer is formed with an oxide of a second metal, and
the second metal is at least one metal selected from the group consisting of titanium, tantalum, zirconium, hafnium, and aluminum.

17. The semiconductor device according to claim 16, wherein
the first metal and the second metal are the same.
